(19) United States
(12) Patent Application Publication
(10) Pub. No.: US 2025/0234468 A1
(43) Pub. Date: Jul. 17, 2025

(54) GLASS SUBSTRATE, GLASS LAMINATE, MEMBER FOR DISPLAY DEVICE, DISPLAY DEVICE, GLASS SUBSTRATE INSPECTION METHOD, AND DISPLAY DEVICE MANUFACTURING METHOD

(71) Applicant: DAI NIPPON PRINTING CO., LTD., Tokyo-to (JP)

(72) Inventors: Makoto NANAUMI, Tokyo-to (JP); Takanori MAEDA, Tokyo-to (JP); Takashi AMIE, Tokyo-to (JP); Kazuyoshi SATAKE, Tokyo-to (JP); Aki KIMURA, Tokyo-to (JP); Mitsuki HORI, Tokyo-to (JP)

(21) Appl. No.: 18/833,328

(22) PCT Filed: Feb. 1, 2023
(86) PCT No.: PCT/JP2023/003174

§ 371 Date: Mar. 27, 2025

(30) Foreign Application Priority Data
Feb. 1, 2022 (JP) 2022-014000
Feb. 1, 2022 (JP) 2022-014002

(51) Int. Cl. H05K 5/03; B32B 17/10; G01B 11/24; G01B 11/30

(52) U.S. Cl. CPC H05K 5/03; B32B 17/10; G01B 11/24; G01B 11/30; B32B 2255/10; B32B 2255/26; B32B 2255/28; B32B 2307/7376; B32B 2457/20

(57) ABSTRACT

The present disclosure provides a glass substrate comprising: a first surface, and a second surface facing the first surface, wherein the glass substrate is a chemically strengthened glass; an average value (Tₐᵥ) of a thickness of the glass substrate is 20 μm or more and 200 μm or less; and at least for the first surface of the glass substrate, an average value (CSₐᵥ) of a surface compressive stress value is 400 MPa or more and 800 MPa or less, and a ratio (CS_{σ}/CSₐᵥ) of a standard deviation (CS_{σ}) of the surface compressive stress value with respect to the average value (CSₐᵥ) of the surface compressive stress value is 0.090 or less.

### TECHNICAL FIELD

The present disclosure relates to a glass substrate, a glass stacked body, a display device, a method for inspecting a glass substrate, and a method for producing a display device.

### BACKGROUND ART

In a display device, a glass or resin cover member is conventionally used for protecting the display device. This cover member protects the display device from impact and scratches, and it is required to have, for example, strength, impact resistance, and chafing resistance. The glass cover member has properties such as a high surface hardness so that it is hardly scuffed, and a high transparency, while the resin cover member has properties such as a lightweight and resistant to breakage. Also, in general, the thicker the cover member, the higher the function of protecting the display device from impact, and the material and thickness of the cover member are selected and used according to, for example, the weight, cost, and the size of the display device.

In recent years, flexible displays such as a foldable display, a rollable display, and a bendable display have been actively developed, among them, the foldable displays, that is, display devices those can be folded have been developed.

In the display device that can be folded, the cover member must also bend in accordance with the movement of the display device, so the cover member that can be folded is applied. In the case of a resin cover member, colorless and transparent polyimide and polyamideimide films have been developed by devising the chemical structures. Also, in the case of a glass cover member, studies are being conducted on cover members that can be folded by thinning glass such as Ultra-Thin Glass (UTG) (for example, refer to Patent Document 1). Among the glasses, glass referred to as chemically strengthened glass has particularly high bending resistance, and the glass is not likely to be cracked by imposing an expanding stress on the glass surface so that the microscopic scratches occurred on the glass surface do not increase when folded.

### CITATION LIST

### Patent Documents

Patent Document 1: Japanese Patent Application Laid-Open (JP-A) No. 2018-188335

### SUMMARY OF DISCLOSURE

### Technical Problem

However, in the case of the chemically strengthened glass, when the thickness is reduced in order to improve the bending resistance, the visual texture (glass texture) peculiar to glass such as clarity may be deteriorated. When a resin layer is formed on a glass substrate to form a stacked body, such deterioration in the glass texture affects the appearance.

Also, since glass has a higher elastic modulus than resin, the ability to protect the display device is higher than that of resin when the thickness is the same. Glass is also high in optically transparent, making it possible to produce display devices with better visibility.

However, when the thickness of the glass is reduced to improve the bending resistance, it will be easier to break and the impact resistance will be deteriorated dramatically. When the glass of the cover member is cracked by an impact from outside, not only the function to protect the display device is deteriorated, but also there is a risk of injuring the user's fingertip or the like with an arisen shard or a sharp edge. Also, in the case of the chemically strengthened glass, when the thickness is reduced in order to improve the bending resistance, the visual texture (glass texture) peculiar to glass such as clarity may be deteriorated. When a resin layer is formed on a glass substrate to form a stacked body, such deterioration in the glass texture affects the appearance.

The present disclosure has been made in view of the above circumstances, and a main object of the present disclosure is to provide a glass substrate having good bending resistance and excellent glass texture.

Also, the present disclosure has been made in view of the above circumstances, and a main object of the present disclosure is to provide a glass stacked body wherein a resin layer is disposed on one surface of a glass substrate, and having excellent bending resistance and impact resistance, and also having excellent glass texture when it is observed from the resin layer side.

### Solution to Problem

One embodiment of the present disclosure provides a glass substrate comprising: a first surface, and a second surface facing the first surface, wherein the glass substrate is a chemically strengthened glass; an average value (Tₐᵥ) of a thickness of the glass substrate is 20 μm or more and 200 μm or less; and at least for the first surface of the glass substrate, an average value (CSₐᵥ) of a surface compressive stress value is 400 MPa or more and 800 MPa or less, and a ratio (CS_{σ}/CSₐᵥ) of a standard deviation (CS_{σ}) of the surface compressive stress value with respect to the average value (CSₐᵥ) of the surface compressive stress value is 0.090 or less.

Also, one embodiment of the present disclosure provides a glass substrate comprising: a first surface and a second surface facing the first surface, wherein the glass substrate is a chemically strengthened glass; an average value (Tₐᵥ) of a thickness of the glass substrate is 20 μm or more and 200 μm or less; at least for the first surface of the glass substrate, an average value (CSₐᵥ) of a surface compressive stress value is 400 MPa or more and 800 MPa or less; and a variation value of a light intensity measured, from a first surface side, by a following method for measuring surface properties is 6.5% or less.

### [Method for Measuring Surface Properties]

(1) Illuminate an illumination light, including four linear bright regions and dark regions, on a surface to be measured that is the first surface of the glass substrate.

(2) Focusing on the surface to be measured with an imaging device, reflect the illumination light on the surface to be measured; receive reflected light including linear bright regions and dark regions corresponding to the bright regions and the dark regions of the illumination light; and detect a light intensity distribution of the reflected light on the surface to be measured.

(3) Divide the light intensity distribution of the reflected light, on the surface to be measured, into 1,100 segment regions in a longitudinal direction of the linear bright region of the reflected light; and determine a light intensity at a position a predetermined value away from a position where a peak value of the light intensity is indicated, per the segment region and per the bright region.

(4) Determine a variation coefficient of the light intensity for each bright region; and calculate an arithmetic average value of variation coefficients for the four bright regions.

Further, the present disclosure provides a glass substrate comprising: a first surface, and a second surface facing the first surface, wherein the glass substrate is a chemically strengthened glass; an average value (Tₐᵥ) of a thickness of the glass substrate is 20 μm or more and 200 μm or less; at least for the first surface of the glass substrate, an average value (CSₐᵥ) of a surface compressive stress value is 400 MPa or more and 800 MPa or less; and a reflected image definition measured from a first surface side is 70% or more.

The present disclosure provides a glass stacked body comprising: the glass substrate described above; and a resin layer disposed on at least one of a first surface side and a second surface side of the glass substrate.

Further, the present disclosure provides a glass stacked body comprising: the glass substrate described above; and a resin layer disposed on a first surface side of the glass substrate, wherein a thickness of the glass stacked body is 50 μm or more and 300 μm or less; and the glass stacked body includes a joining layer disposed on a first surface side of the glass substrate, and a total thickness of the joining layer, with respect to a thickness of the glass stacked body, is 25 or less.

Also, the present disclosure provides a glass stacked body comprising: the glass substrate a described above; and a resin layer disposed on a first surface side of the glass substrate, wherein a thickness of the glass stacked body is 50 μm or more and 300 μm or less; and in the glass stacked body, the resin layer is in contact with the glass substrate.

Furthermore, the present disclosure provides a glass stacked body comprising: a glass substrate including a first surface, and a second surface facing the first surface; and a resin layer disposed on a first surface side of the glass substrate, wherein the glass substrate is a chemically strengthened glass, and a thickness of the glass substrate is 20 μm or more and 200 μm or less; at least for the first surface of the glass substrate, an average value (CSₐᵥ) of a surface compressive stress value is 400 MPa or more and 800 MPa or less; a thickness of the glass stacked body is 50 μm or more; and for the glass stacked body, a variation value of a light intensity measured, from a resin layer side, by a following method for measuring surface properties is 10.5% or less.

### [Method for Measuring Surface Properties]

(1) Illuminate an illumination light, including four linear bright regions and dark regions, on a surface to be measured that is a surface of the resin layer of the glass stacked body.

(2) Focusing on the surface to be measured with an imaging device, reflect the illumination light on the surface to be measured; receive reflected light including linear bright regions and dark regions corresponding to the bright regions and the dark regions of the illumination light; and detect a light intensity distribution of the reflected light on the surface to be measured.

(3) Divide the light intensity distribution of the reflected light, on the surface to be measured, into 1,100 segment regions in a longitudinal direction of the linear bright region of the reflected light; and determine a light intensity at a position a predetermined value away from a position where a peak value of the light intensity is indicated, per the segment region and per the bright region.

(4) Determine a variation coefficient of the light intensity for each bright region; and calculate an arithmetic average value of variation coefficients for the four bright regions.

Also, the present disclosure provides a glass stacked body comprising: a glass substrate including a first surface and a second surface facing the first surface; and a resin layer disposed on a first surface side of the glass substrate, wherein the glass substrate is a chemically strengthened glass, and a thickness of the glass substrate is 20 μm or more and 200 μm or less; at least for the first surface of the glass substrate, an average value (CSₐᵥ) of a surface compressive stress value is 400 MPa or more and 800 MPa or less; and
a thickness of the glass stacked body is 50 μm or more, and a reflected image definition measured from a resin layer side is 651 or more.

Further, the present disclosure provides a member for a display device comprising the glass stacked body described above; and a functional layer disposed on a resin layer side of the glass stacked body.

Also, the present disclosure provides display device comprising: a display panel; and the glass substrate described above, the glass stacked body described above, or the member for a display device described above disposed on an observer side of the display panel.

Further, the present disclosure provides a method for inspecting a glass substrate including a first surface and a second surface facing the first surface, and the glass substrate is a chemically strengthened glass, the method comprising: a step of selecting a glass substrate having a variation value of a light intensity measured, from a first surface side, by a following method for measuring surface properties of 6.5% or less.

### [Method for Measuring Surface Properties]

(1) Illuminate an illumination light, including four linear bright regions and dark regions, on a surface to be measured that is the first surface of the glass substrate.

(2) Focusing on the surface to be measured with an imaging device, reflect the illumination light on the surface to be measured; receive reflected light including linear bright regions and dark regions corresponding to the bright regions and the dark regions of the illumination light; and detect a light intensity distribution of the reflected light on the surface to be measured.

(3) Divide the light intensity distribution of the reflected light, on the surface to be measured, into 1,100 segment regions in a longitudinal direction of the linear bright region of the reflected light; and determine a light intensity at a position a predetermined value away from a position where a peak value of the light intensity is indicated, per the segment region and per the bright region.

(4) Determine a variation coefficient of the light intensity for each bright region; and calculate an arithmetic average value of variation coefficients for the four bright regions.

Also, the present disclosure provides a method for inspecting a glass stacked body including a glass substrate that is a chemically strengthened glass and including a first surface, and a second surface facing the first surface; and a resin layer disposed on a first surface side of the glass substrate, the method comprising a step of selecting a glass stacked body having a variation value of a light intensity measured, from a resin layer side, by a following method for measuring surface properties of 10.5% or less.

### [Method for Measuring Surface Properties]

(1) Illuminate an illumination light, including four linear bright regions and dark regions, on a surface to be measured that is a surface of the resin layer of the glass stacked body.

(2) Focusing on the surface to be measured with an imaging device, reflect the illumination light on the surface to be measured; receive reflected light including linear bright regions and dark regions corresponding to the bright regions and the dark regions of the illumination light; and detect a light intensity distribution of the reflected light on the surface to be measured.

(3) Divide the light intensity distribution of the reflected light, on the surface to be measured, into 1,100 segment regions in a longitudinal direction of the linear bright region of the reflected light; and determine a light intensity at a position a predetermined value away from a position where a peak value of the light intensity is indicated, per the segment region and per the bright region.

(4) Determine a variation coefficient of the light intensity for each bright region; and calculate an arithmetic average value of variation coefficients for the four bright regions.

The present disclosure also provides a method for inspecting a glass stacked body including a glass substrate that is a chemically strengthened glass and including a first surface, and a second surface facing the first surface; and a resin layer disposed on a first surface side of the glass substrate, the method comprising a step of selecting a glass stacked body having a reflected image definition, measured from a resin layer side, of 65% or more.

Further the present disclosure provides a method for producing a display device, the method comprising a glass substrate inspecting step of carrying out the method for inspecting a glass substrate described above.

Also, the present disclosure provides a method for producing a display device, the method comprising a glass stacked body inspecting step of carrying out the method for inspecting a glass stacked body described above.

### Advantageous Effects of Disclosure

The present disclosure exhibits effect of providing a glass substrate and a glass stacked body having good bending resistance and excellent glass texture.

### BRIEF DESCRIPTION OF DRAWINGS

FIG. 1 is a schematic cross-sectional view exemplifying a glass substrate of the present disclosure.

FIG. 2 are concept images of the surface compressive stress and tensile stress applied to a glass substrate.

FIG. 3 are concept images of the surface compressive stress and tensile stress applied to a glass substrate.

FIG. 4 are a concept image of a potassium ion distribution of a surface of a glass substrate, and a graph of a concentration distribution of the potassium ion by EDX.

FIG. 5 are a concept image of a potassium ion distribution of a surface of a glass substrate, and a graph of a concentration distribution of the potassium ion by EDX.

FIG. 6 are schematic views for explaining a U-shape bending test.

FIG. 7 is a photograph for explaining a warp of a glass substrate.

FIG. 8 are schematic cross-sectional views exemplifying a glass stacked body of the present disclosure.

FIG. 9 is a schematic cross-sectional view exemplifying a display device of the present disclosure.

FIG. 10 are a schematic view of a surface property measurement device, and a schematic plan view exemplifying a mask constituting an illuminating portion used in the present disclosure.

FIG. 11 is a schematic cross-sectional view of a sample for evaluation used in the method for measuring surface properties of the present disclosure.

FIG. 12 is a view exemplifying an image taken by the imaging device of the surface property measurement device used in the present disclosure.

FIG. 13 is a graph exemplifying a light intensity distribution the light reflected on a surface to be measured.

FIG. 14 are a schematic view of an image definition measurement device, and a schematic plan view exemplifying a mask constituting an illuminating portion used in the present disclosure.

FIG. 15 is a graph exemplifying a light intensity distribution the light reflected on a surface to be measured.

FIG. 16 are evaluation results of the glass texture by CS_{σ}/CSₐᵥ in Examples 1-1 to 1-9 and Comparative Examples 1-1 to 1-6.

FIG. 17 are evaluation results of the glass texture by T_{σ}/Tₐᵥ in Examples 1-1 to 1-9 and Comparative Examples 1-1 to 1-6.

FIG. 18 are schematic cross-sectional views exemplifying the glass stacked body in the second embodiment of the present disclosure.

FIG. 19 are schematic cross-sectional views exemplifying the glass stacked body in the third embodiment of the present disclosure.

FIG. 20 is a schematic cross-sectional view exemplifying a member for a display device of the present disclosure.

### DESCRIPTION OF EMBODIMENTS

Embodiments in the present disclosure are hereinafter explained with reference to, for example, drawings. However, the present disclosure is enforceable in a variety of different forms, and thus should not be taken as is limited to the contents described in the embodiments exemplified as below. Also, the drawings may show the features of the present disclosure such as width, thickness, and shape of each part schematically comparing to the actual form in order to explain the present disclosure more clearly in some cases; however, it is merely an example, and thus does not limit the interpretation of the present disclosure. Also, in the present descriptions and each drawing, for the factor same as that described in the figure already explained, the same reference sign is indicated and the detailed explanation thereof may be omitted.

In the present descriptions, in expressing an aspect wherein some member is placed on the other member, when described as merely “on” or “below”, unless otherwise stated, it includes both of the following cases: a case wherein some member is placed directly on or directly below the other member so as to be in contact with the other member, and a case wherein some member is placed on the upper side or the lower side of the other member via yet another member. Also, in the present descriptions, on the occasion of expressing an aspect wherein some member is placed on the surface of the other member, when described as merely “on the surface side” or “on the surface”, unless otherwise stated, it includes both of the following cases: a case wherein some member is placed directly on or directly below the other member so as to be in contact with the other member, and a case wherein some member is placed on the upper side or the lower side of the other member via yet another member.

Also, in the present disclosure, the first surface refers to one of the two surfaces with the largest surface area of the glass substrate, and the second surface refers to the surface facing the first surface.

A glass substrate, a glass stacked body, a member for a display device, a display device, a method for inspecting a glass substrate, method for inspecting a glass stacked body, and a method for producing a display device in the present disclosure are hereinafter described in detail.

### A. Glass Substrate (First Embodiment)

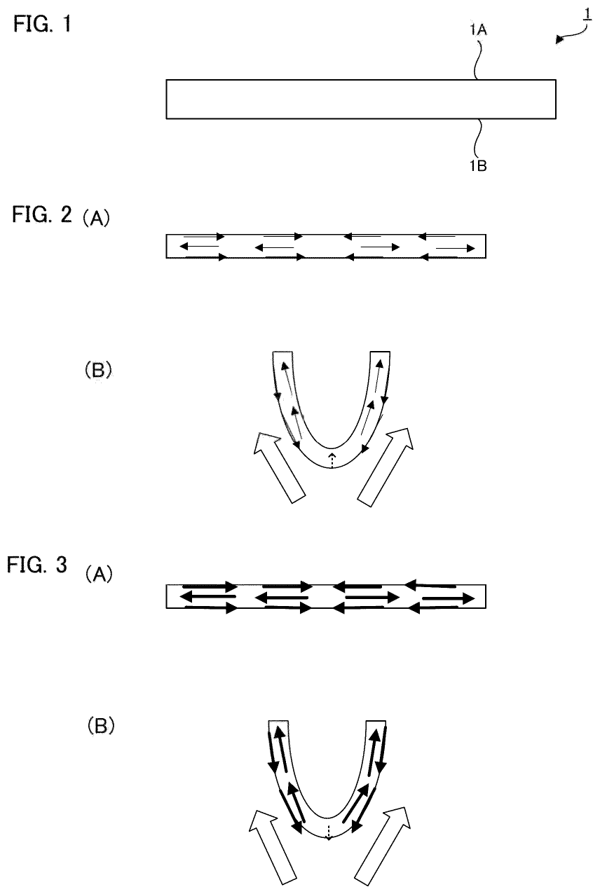

FIG. 1 is a schematic cross-sectional view exemplifying a glass substrate of the present embodiment. As shown in FIG. 1, the glass substrate 1 in the present embodiment comprises a first surface 1A, and a second surface 1B facing the first surface 1A, wherein the glass substrate 1 is a chemically strengthened glass; an average value (Tₐᵥ) of a thickness of the glass substrate is 20 μm or more and 200 μm or less; at least for the first surface 1A, the average value (CSₐᵥ) of a surface compressive stress value is 400 MPa or more and 800 MPa or less; and the ratio (CS_{σ}/CSₐᵥ) of a standard deviation (CS_{σ}) of the surface compressive stress value with respect to the average value (CSₐᵥ) of the surface compressive stress value is 0.090 or less.

Incidentally, in the present disclosure, the standard deviation is a value indicated by the following formula.

$$\sqrt{\frac{\sum {( x - \overline{x} )}^{2}}{( n - 1 )}} \qquad [ Mathematic 1 ]$$

In the glass substrate in the present embodiment, since the chemically strengthened glass is used, and the average value (Tₐᵥ) of the thickness is in the predetermined range, bending resistance may be improved. Also, the bending resistance can be further improved by setting the average value (CSₐᵥ) of the surface compressive stress value of at least for the first surface of the glass substrate to a predetermined range.

FIG. 2 and FIG. 3 show concept images of the surface compressive stress and tensile stress applied to the glass substrate. As shown in FIG. 2(A), FIG. 3(A), the chemically strengthened glass is a glass wherein mechanical properties are strengthened by a chemical method by partially exchanging, for example, a sodium ion with a potassium ion, in the vicinity of the surface of glass, and a compressive stress layer exists on the surface, and a tensile stress layer exists inside thereof. As shown in FIG. 2(A), the glass substrate whose surface compressive stress value is too low will break due to the tensile stress generated at the bent portion during bending, resulting in cracking (FIG. 2(B)). Also, as shown in FIG. 3(A), the glass substrate whose surface compressive stress value is too high will break from inside due to the influence of tensile strength inside the glass substrate and the tensile stress generated during bending, resulting in cracking (FIG. 3(B)).

In contrast to this, the bending resistance can be further improved and a breakage during bending may be suppressed, since the average value (CSₐᵥ) of the surface compressive stress value of at least for the first surface of the glass substrate in the present embodiment, is in a predetermined range.

Further, the inventors have found out that when the degree of variation in the surface compressive stress value is small, the glass texture is improved. The reason therefore is presumed as follows.

As described above, the chemically strengthened glass includes a compressive stress layer on the surface of the first surface and the second surface. In other words, the chemically tempered glass is a glass wherein much potassium is present on its surface, and compressive stress is applied to its surface. The inventors have found out that the deterioration of the glass texture is due to a locally different refractive index of the glass substrate due to the uneven distribution of potassium. Further, based on the knowledge that the unevenness of the potassium distribution is correlated with the variation of the surface compressive stress value, the inventors have found out that when the degree of variation in the surface compressive stress value is small, the glass texture is improved.

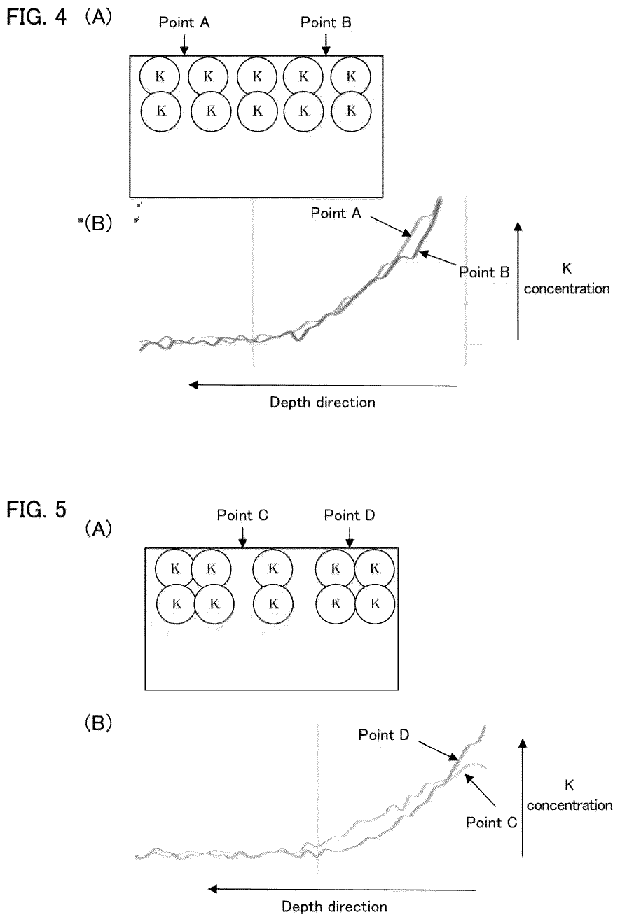

FIG. 4 and FIG. 5 show concept images of the potassium ion distribution of the surface of the glass substrate, and graphs of the concentration distribution of the potassium ion by an energy dispersive X-ray analysis (EDX). As shown in FIGS. 5, when potassium is distributed unevenly on the surface of the glass substrate, it is inferred that the glass texture deteriorates since the refractive index of the glass substrate differs locally. Meanwhile, when the potassium is uniformly distributed as shown in FIGS. 4, it is inferred that the glass texture improves since the refractive index is not locally varied.

Further, the inventors have found out that the degree of variation in the surface compressive stress value can be evaluated accurately so that the glass texture is securely improved by using the ratio (CS_{σ}/CSₐᵥ) of the standard deviation (CS_{σ}) of the surface compressive stress value with respect to the average value (CSₐᵥ) of the surface compressive stress value of the glass substrate, that is, the variation coefficient, as a parameter for accurately evaluating the variation in the surface compressive stress value.

Therefore, in the present embodiment, it is possible to obtained a glass substrate with excellent bending resistance and excellent glass texture. Thus, the glass substrate in the present embodiment may be folded so that it may be used for a wide variety of display devices, for example, it may be used as a member for a foldable display. The glass substrate in the present embodiment is hereinafter described in detail.

### 1. Chemically Strengthened Glass

The glass substrate in the present embodiment is chemically strengthened glass. As described above, the chemically strengthened glass has better impact resistance and bending resistance compared to non-strengthened glass. Also, the chemically strengthened glass has an effect that it has excellent mechanical strength and may be made thin accordingly.

The chemically strengthened glass is a glass wherein mechanical properties are strengthened by a chemical method by partially exchanging, for example, a sodium ion with a potassium ion, in the vicinity of the surface of glass, and includes a compressive stress layer on the surface of the first surface and the surface of the second surface. In other words, the chemically strengthened glass is a glass wherein much potassium is present on its surface, and compressive stress is applied to its surface.

As for the chemically strengthened glass in the present embodiment, a glass substrate can be identified to be a chemically strengthened glass by the following method.

When the glass substrate is divided into 10 regions in the thickness direction, and the potassium ion concentration in each region is regarded as d1, d2, d3, . . . d10 from the outermost surface side, and when the potassium ion concentration satisfies both d1>d5 and d10>d5, the glass substrate can be identified to be a chemically strengthened glass. The distribution of the potassium concentration in the thickness direction can be measured, for example, by an energy dispersive X-ray analysis (EDX). Specifically, to the side surface of the glass substrate, using X-MaxN from Oxford Instruments, EDX mapping is carried out to the thickness direction of the side surface of the glass substrate at an acceleration voltage of 10 kV, and the potassium concentration can be determined quantitatively.

The shape of the glass substrate is usually a rectangular solid, and it is a hexahedron. The glass substrate includes two surfaces (first surface and second surface) and four side surfaces. The glass substrate is usually a six-surface-strengthened glass wherein all surfaces are subjected to chemically strengthening treatment. The six-surface-strengthened glass can be obtained, for example, by subjecting a chemical strengthening treatment to a glass substrate. Also, the glass substrate may be a two-surface-strengthened glass obtained by cutting the six-surface-strengthened glass to a desired size.

Examples of the glass constituting the chemically strengthened glass substrate may include aluminosilicate glass, soda-lime glass, borosilicate glass, lead glass, alkali barium glass, and aluminoborosilicate glass.

The chemically strengthened glass can be produced by subjecting a chemically strengthening treatment to a glass plate, and then, washing and drying. Usually, in the chemically strengthening treatment, a glass plate is brought into contact with a melt of metal salts (such as potassium nitrate) including metal ions with a large ion radius (typically K ions) by, for example, an immersion. Thereby, metal ions with small ionic radius (typically Na ions) in the glass plate are replaced with metal ions with large ionic radius (typically K ions).

### 2. Surface Compressive Stress Value CS

### (1) Average Value (CSₐᵥ)

In the glass substrate in the present embodiment, at least for the first surface, the average value (CS) of the surface compressive stress value is 400 MPa or more and 800 MPa or less. Incidentally, the chemically strengthened glass usually has a symmetrical stress distribution in the thickness direction due to its production method, and the average value (CSₐᵥ) of the surface compressive stress value, and the ratio (CS_{σ}/CSₐᵥ) of the standard deviation (CS_{σ}) of the surface compressive stress value with respect to the average value (CSₐᵥ) of the surface compressive stress value described later of the first surface and the second surface are equivalent values. Specifically, for the first surface and the second surface, the ratios (CS_{σ}/CSₐᵥ) of the standard deviation (CS_{σ}) of the surface compressive stress value with respect to the average value (CSₐᵥ) of the surface compressive stress value are preferably within 20%.

When the average values (CSₐᵥ) of the surface compressive stress value for the first surface and the second surface are different, the stress distribution in the thickness direction becomes asymmetric, which may change the central axis of the glass, causing swell or glass fracture in some cases.

When the average value (CSₐᵥ) of the surface compressive stress value is too low (for example, FIG. 2), the bending resistance decreases. Also, when the average value (CSₐᵥ) of the surface compressive stress value is too high (for example, FIG. 3), the internal tensile stress becomes too high and the bending resistance decreases. Also, the average value (CSₐᵥ) of the surface compressive stress value is preferably 450 MPa or more and 750 MPa or less.

As for the method for measuring the average value (CSₐᵥ) of the surface compressive stress value, by measuring the stress distribution in the thickness direction of the glass from the first surface or the second surface, using a refractometer type glass surface stress meter. FSM-6000LE from Iuceo co., Ltd., and the stress value of the outermost surface can be regarded as the surface compressive stress value CS.

Incidentally, the measurement conditions (device design) of the FSM-6000LE are as follows.
Light source: 365 nm
Refractive index (prism): 1.756
Optical path length: 192.7 mm

The average value (CSₐᵥ) of the surface compressive stress value of the first surface is obtained by measuring the surface compressive stress value at multiple points (such as 5 points or more and 15 points or less) of the first surface of the glass substrate, and determining the average value of the obtained surface compressive stress value of the multiple points.

Specifically, it can be obtained by preparing 9 areas by dividing the first surface of the glass substrate into 3 respective areas in the first direction (x direction) and the second direction (y direction) perpendicular to the first direction, in the surface; measuring the surface compressive stress value CS at one point in each area; and determining the arithmetic average of the 9 measurement points. For example, when the first surface of the glass substrate is 100 mm×100 mm, it can be obtained by measuring one point per 30 mm×30 mm, and determining the arithmetic average of the 9 measurement points. Also, the average value (CSₐᵥ) of the surface compressive stress value of the second surface may be obtained by the similar method.

(2) CS_{σ}/CSₐᵥ

In the glass substrate in the present embodiment, at least for the first surface, the ratio (CS_{σ}/CSₐᵥ) of the standard deviation (CS_{σ}) of the surface compressive stress value with respect to the average value (CSₐᵥ) of the surface compressive stress value, that is, the variation coefficient of the glass substrate is 0.090 or less. CS_{σ}/CSₐᵥ is preferably 0.070 or less. CS_{σ}/CSₐᵥ is the variation coefficient of the surface compressive stress value at multiple measurement points measured by the method described above.

### (3) Method for Adjusting

In the present embodiment, a chemically strengthening treatment (ion exchanging treatment) is carried out so as to satisfy the average value (CSₐᵥ) and variation coefficient (CS_{σ}/CSₐᵥ) of the surface compressive stress value described above.

The average value (CSₐᵥ) of the surface compressive stress value and the depth (DOL) value of the compressive stress layer described later can be adjusted by adjusting the immersion time in molten salts such as potassium nitrate.

For example, the average value (CSₐᵥ) of the surface compressive stress value and the depth (DOL) value of the compressive stress layer described later increase as the immersion time in molten salts such as potassium nitrate increases. Also, after the immersion in molten salt such as potassium nitrate, washing is carried out to wash off the nitric acid adhered to the glass substrate, and by making the retention time until washing after immersion longer, it is possible to increase the DOL while suppressing the increase of CSₐᵥ.

Also, examples of the method for making the CS_{σ}/CSₐᵥ to be the value described above or less may include: 1) a method wherein the distortion of the glass substrate generated during chemically strengthening treatment is reduced by devising a jig, for example, when immersing in molten salt; and 2) a method wherein the heating temperature of the molten salt such as potassium nitrate, into which the glass substrate is immersed, is reduced, and the immersion time is increased (carrying out the ion exchange gradually).

The specific conditions for the chemically strengthening treatment (ion exchanging treatment) vary depending on the type of the glass, and the chemically strengthening treatment can be carried out by, for example, immersing a glass plate for 1 minute to 120 minutes in a molten salt such as potassium nitrate heated to 350 to 450° C. The glass plate is then washed with water to wash off the nitric acid adhered to the glass plate.

### 3. Thickness T

### (1) Average Value (Tₐᵥ)

The lower limit of the average value (Tₐᵥ) of the thickness of the glass substrate in the present embodiment is 20 μm or more, preferably 25 μm or more, and further preferably 30 μm or more. Meanwhile, the upper limit is 200 μm or less, and preferably 150 μm or less. The specific range is 20 μm or more and 200 μm or less preferably 25 μm or more and 200 μm or less, and further preferably 30 μm or more and 150 μm or less. When the thickness of the glass substrate is thin as in the above range, excellent flexibility may be obtained, and at the same time, sufficient hardness may be obtained so as to be excellent in bending resistance. It is also possible to suppress curling of the glass substrate. Further, it is preferable in terms of reducing the weight of the glass substrate. The thickness of the glass substrate refers to the distance between the first surface and the second surface of the glass substrate. Also, similarly to the method for measuring the average value (CSₐᵥ) of the surface compressive stress value, the average value (Tₐᵥ) of the thickness of the glass substrate is obtained by measuring the thickness at multiple points (such as 5 points or more and 15 points or less) of the glass substrate, and determining the average value of the obtained thickness of the multiple points. Specifically, it can be obtained by preparing 9 areas by dividing the glass substrate into 3 respective areas in the first direction (x direction) and the second direction (y direction) perpendicular to the first direction, in a surface parallel to the first surface and the second surface; measuring the thickness at one point in each area; and determining the arithmetic average of the 9 measurement points. For example, when the first surface of the glass substrate is 100 mm×100 mm, it can be obtained by measuring one point per 30 mm×30 mm, and determining the arithmetic average of the 9 measurement points. Also, when the first surface of the glass substrate is less than 100 mm×100 mm, the area of the first surface is divided into 9 areas, and then, 9 points are measured. Meanwhile, when the first surface of the glass substrate exceeds 100 mm×100 mm, the region of 100 mm×100 mm in the central part of the glass substrate is divided into 9 areas, and 9 points are measured.

The thickness is measured using a Scanning Electron Microscope (SEM) S-4800 from Hitachi High-Tech Corporation, under the following conditions.
Acceleration voltage: 3.0 kV
Emission current: 10 μA
Magnification: 500-fold

Using epoxy resin as a cold embedding resin, a sample is prepared by embedding a glass substrate into the epoxy resin, finishing it using Tegrapol-35 from Struers LLC as a mechanical polishing device, and subjecting to a platinum sputtering treatment.

(2) T_{σ}/Tₐᵥ

In the present embodiment, the lower limit of the ratio (T_{σ}/Tₐᵥ) of the standard deviation (T_{σ}) of the thickness with respect to the average value (Tₐᵥ) of the thickness of the glass substrate, that is, the variation coefficient, is preferably 0.003 or more, and further preferably 0.005 or more. Meanwhile, the upper limit is preferably 0.050 or less, and further preferably 0.030 or less. As for the specific range, it is preferably 0.003 or more and 0.050 or less, and further preferably 0.005 or more and 0.030 or less. When T_{σ}/Tₐᵥ is too low, the close adhesiveness between the resin layer and the glass substrate may be poor. When T_{σ}/Tₐᵥ is too high, the glass texture may deteriorate. T_{σ}/Tₐᵥ is the variation coefficient of the thickness at multiple measurement points measured by the method described above.

### 4. Others

### (1) Depth DOL of Compressive Stress Layer

In the glass substrate in the present embodiment, the lower limit of the depth (DOL) of the compressive stress layer is preferably 5 μm or more, more preferably 6 μm or more, and further preferably 6 μm or more. Meanwhile, the upper limit is preferably 20 μm or less, more preferably 18 μm or less, and further preferably 12 μm or less. The specific range is preferably 5 μm or more and 20 μm or less, more preferably 6 μm or more and 18 μm or less, and further preferably 6 μm or more and 12 μm or less. When the DOL is the above value or more, bending resistance is more reliably improved. When the DOL is the above value or less, it is possible to suppress the internal tensile stress becoming too high to cause a breakage. The depth (DOL) of the compressive stress layer is the thickness of the glass surface layer wherein the compressive stress is generated by ion exchange, and can be measured by a stress measurement device (a refractometer type glass surface stress meter FSM-6000LE).

### (2) Internal Tensile Stress CT

In the glass substrate in the present embodiment, the lower limit of the internal tensile stress (CT) is preferably 80 MPa or more, and more preferably 100 MPa or more. Meanwhile, the upper limit is preferably 350 MPa or less, and more preferably 250 MPa or less. As for the specific range, it is preferably 80 MPa or more and 350 MPa or less, and more preferably 00 MPa or more and 250 MPa or less.

When the internal tensile stress (CT) is the above value or more, bending resistance is more reliably improved. When the internal tensile stress (CT) is the above value or less, it is possible to suppress the internal tensile stress becoming too high, and a breakage can be appropriately reduced.

Incidentally, the internal tensile stress (CT) is the tensile stress generated in the inner layer of the glass to offset the compressive stress generated between the outer surfaces of the glass after ion exchange. CT can be calculated from the measured CS and DOL.

Specifically, it is indicated by CT=(CS×DOL)/(t−2*DOL). Where CS is the surface stress, DOL is the depth of the compressive stress layer, and “t” is the thickness of the glass.

### (5) Bending Resistance

The glass substrate in the present disclosure preferably has a bending resistance. Specifically, the bending resistance of the glass substrate can be evaluated by carrying out a U-shape bending test described below.

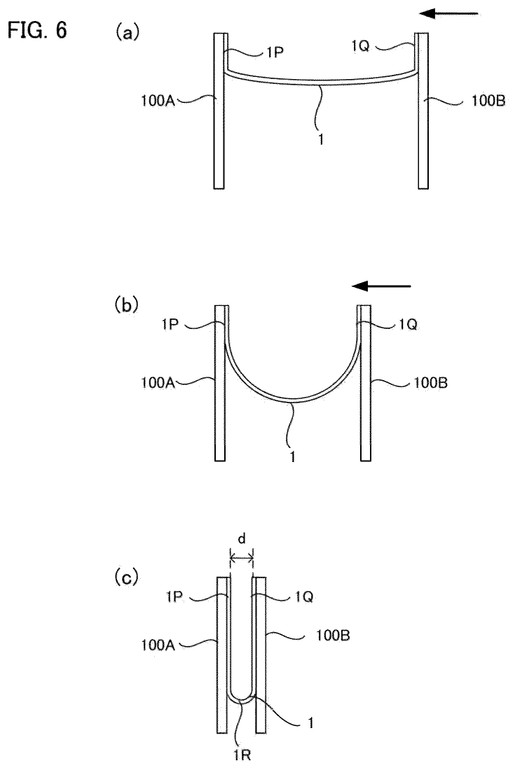

The U-shape bending test is carried out as follows. Firstly, a test piece that is a glass substrate having a size of 20 mm×100 mm, is prepared. Then, as shown in FIG. 6(a), a short side portion 1P and a short side portion 1Q facing the short side portion 1P of the glass substrate 1 are respectively fixed by parallelly arranged fixing portions 100A, 100B. As shown in FIG. 6(a), the fixing portion 100B is movable by sliding in horizontal direction. Then, as shown in FIG. 6(b), by moving the fixing portion 100B so as to be closer to the fixing portion 100A, the glass substrate 1 is bent into a U-shape. Further, as shown in FIG. 6(c), by moving the fixing portion 100B, a distance “d” between the two facing short side portions 1P, 1Q of the glass substrate 1, fixed by the fixing portions 100A, 100B, is gradually reduced until a crack or a fracture occurs in the glass substrate 1. In doing so, the bending test is carried out so that bent portion 1R of the glass substrate 1 does not protrude from the lower end edge of the fixing portions 100A, 100B. For example, when the distance “d” between the two facing short side portions 1P and 1Q is 10 mm, the outer diameter of the bent portion 1R is regarded as 10 mm.

In the U-shape bending test, the distance “d” between the facing short side portions 1P and 1Q of the glass substrate 1, when a crack or a fracture occurs in the glass substrate is, for example, 10 mm or less, preferably 6 mm or less, and particularly preferably 4 mm or less. Incidentally, the smaller the distance “d” between the facing short side portions 1P, 10 of the glass substrate 1, the higher the bending resistance.

### 6. Warp of Glass Substrate

The thickness of the glass substrate in the present embodiment is thin such as 20 μm or more and 200 μm or less. In general, the thinner the glass, the more deflection occurs during the chemical strengthening process, and the worse the stress distribution. Meanwhile, as described above, the variation of surface compressive stress value of the glass substrate in the present embodiment is small. When the variation in the surface compressive stress value of the glass substrate is small in this way, the gap (floating of the glass substrate) between the glass substrate and the base table, when disposed on a horizontal base table, can be reduced even when the thickness of the glass substrate is thin such as 20 μm or more and 100 μm or less and the glass weight is small.

Specifically, when a test piece of the glass substrate with a size of 320 nm×280 mm is prepared, and the test piece is disposed on a horizontal base table for 5 minutes, the maximum distance of the gap (floating of the glass substrate) between the base table and the test piece measured with a gap gauge (SUS plate) can be 20 mm or less, and preferably 5 mm or less.

Also, when a test piece of the glass substrate with a size of 100 mm×100 mm is prepared, and this test piece is disposed on a horizontal base table for 5 minutes, the maximum distance of the gap (floating of the glass substrate) between the base table and the test piece can be 0.6 mm or less, and preferably 0.3 mm or less.

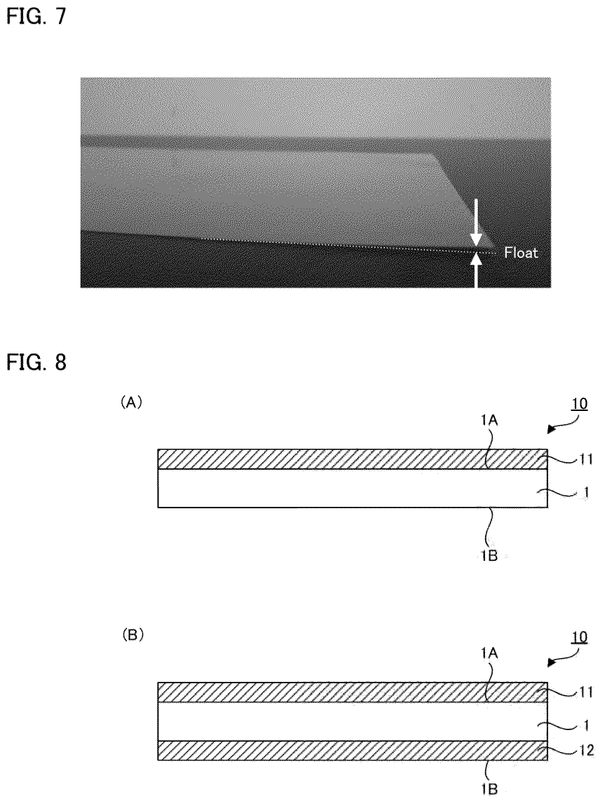

Meanwhile, when the variation in the surface compressive stress value is large, the thinner the thickness of the glass substrate, the more likely it is to float, due to the smaller weight of the glass. Incidentally, FIG. 7 shows a photograph for explaining a warp of the glass substrate.

### 7. Glass Texture

The glass substrate in the present embodiment has excellent glass texture. Particularly, the variation value of the light intensity measured, from the first surface side, by the predetermined method for measuring surface properties may be a predetermined value or less. Also, the image definition calculated from the light intensity distribution of the reflected light can be increased. Since the variation value of the light intensity, image definition, and method for measuring are similar to “B. Glass substrate (second embodiment)”, “C. Glass substrate (third embodiment)” described below, the explanation herein is omitted.

### 8. Use Application

The glass substrate in the present disclosure may be used as, for example, a cover member of a display device. When used as a cover member of a display device, the glass substrate is preferably disposed so that the first surface side of the glass substrate is on the outer side (observer side). Specifically, the glass substrate in the present disclosure may be used as a cover member of a display device used for an electronic device such as smart phones, tablet terminals, wearable terminals, personal computers, televisions, digital signages, public information displays (PIDs), and car mounted displays. Among the above, the glass substrate in the present disclosure may be preferably used for a flexible display such as a foldable display, a rollable display, and a bendable display; and more preferably used for a foldable display.

### B. Glass Substrate (Second Embodiment)

The glass substrate in the present embodiment comprise: a first surface and a second surface facing the first surface, wherein the glass substrate is a chemically strengthened glass; an average value (Tₐᵥ) of a thickness of the glass substrate is 20 μm or more and 200 μm or less; at least for the first surface of the glass substrate, an average value (CSₐᵥ) of a surface compressive stress value is 400 MPa or more and 800 MPa or less; and a variation value of a light intensity measured, from a first surface side, by the method for measuring surface properties is 6.5% or less.

In the glass substrate in the present embodiment, since the variation value of the light intensity measured by the method for measuring surface properties described below is low as the predetermined value described above or less, it has excellent glass texture. Further in the glass substrate in the present embodiment, since the chemically strengthened glass is used, and the average value (Tₐᵥ) of the thickness and the average value (CSₐᵥ) of a surface compressive stress value of at least for the first surface are in the predetermined range, bending resistance may be improved.

### 1. Variation Value of Light Intensity

The variation value of the light intensity measured by using the method for measuring surface properties described below indicates the degree of variation of the light intensity due to surface properties such as convexoconcave and undulation of the surface of the glass substrate, and the lower this value, the better the glass texture. The variation value of the light intensity of the glass substrate in the present embodiment, measured from the first surface side, is 6.5 or less, preferably 6.0% or less, and further preferably 5.5% or less.

### [Method for Measuring Surface Properties]

(1) Illuminate an illumination light, including four linear bright regions and dark regions, on a surface to be measured that is the first surface of the glass substrate.

(2) Focusing on the surface to be measured with an imaging device, reflect the illumination light on the surface to be measured; receive reflected light including linear bright regions and the dark regions corresponding to the bright regions and the dark regions of the illumination light; and detect a light intensity distribution of the reflected light on the surface to be measured.

(3) Divide the light intensity distribution of the reflected light, on the surface to be measured, into 1,100 segment regions in a longitudinal direction of the linear bright region of the reflected light; and determine a light intensity at a position a predetermined value away from a position where a peak value of the light intensity is indicated, per the segment region and per the bright region.

(4) Determine a variation coefficient of the light intensity for each bright region; and calculate an arithmetic average value of variation coefficients for the four bright regions.

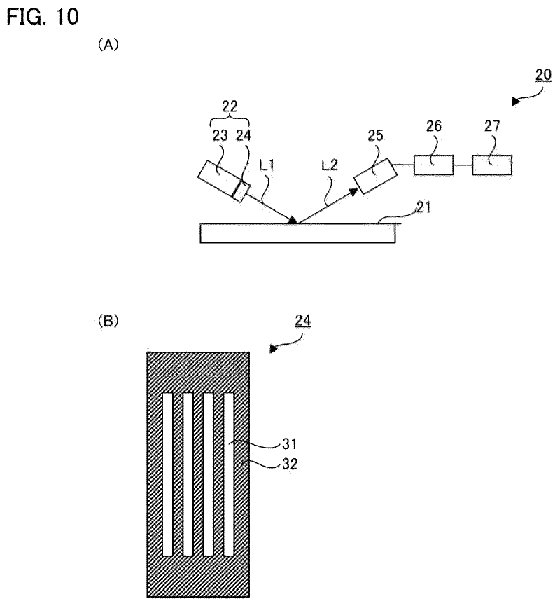

Specifically, the surface property measurement device 20 shown in FIG. 10(A) is used. The surface property measurement device 20 includes an illuminating portion 22 configured to illuminate an illustration light L1, including linear bright, regions and dark regions, on a surface to be measured 21; an imaging device 25, focusing on the surface to be measured 21, configured to reflect the illumination light on the surface to be measured 21, receive reflected light L2 including linear bright regions and dark regions corresponding to the bright regions and the dark regions of the illumination light L1, and detect a light intensity distribution of the reflected light. 12 on the surface to be measured 21; a first processing portion 26 configure to determine a light intensity at a position a predetermined value away from a position where a peak value of the light intensity in the bright region is indicated, in the light intensity distribution of the reflected light L2 on the surface to be measured 21; and a second processing portion 27 configured to quantify the variation of the light intensity determined by the first processing portion 26.

The illuminating portion 22 is one wherein a mask 24 including a metal plate and rectangular openings 31 those pass through the metal plate 32 shown in FIG. 10(B), is directly adhered to the OLED (Organic Light Emitting Diode) light source 23 described below. As shown in FIG. 10(B), the mask includes transmission regions consisted from four rectangular openings 31, and the rectangular transmission region has a length of 65 mm, a line width of 2.0 mm, and a pitch of 4.0 mm.

The distance between the light source 23 and the surface to be measured 21 of the glass substrate 1 is 33 cm, and the incident angle of the illumination light emitted from the illuminating portion is 60°. Also, the distance between the measurement device 25 and the surface to be measured 21 is 33 cm, and the light receiving angle of the reflected light of the measurement device 25 is 60°. When the light from the LED light source passes through the mask 24, illumination light L1 including linear bright regions and dark regions is illuminated on the surface to be measured 21.

EELM-SKY-300-W from Ecorica Inc. is used as the LED light source, and a digital single-lens reflex camera D5600 from Nikon Corporation is used as the imaging device. For the lens, AF-P DX NIKKOR 18-55 mm f/3.5-5.6G VR from Nikon Corporation is used. The camera settings are set to an aperture of f/22, an exposure time of ⅛ seconds, ISO-100, and a focal length of 55 mm.

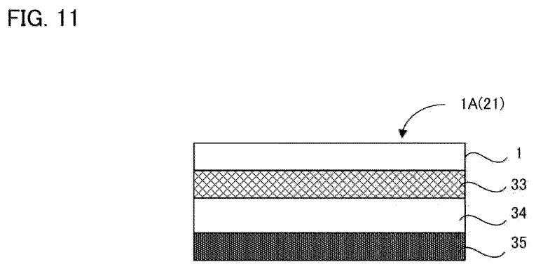

The schematic cross-sectional view of a sample for evaluation is shown in FIG. 11. One including an optically clear adhesive sheet 33 (OCA, NCF D692 from LINTEC Corporation, with a thickness of 5 μm), glass 34 (OA-10 from Nippon Electric Glass Co., Ltd. (alkali-free glass) 0.5 mm), and black PET film 35 disposed on the surface of a glass substrate 1 including a surface to be measured 21 (such as first surface 1A) that is opposite to the surface to be measured 21, is used.

A spot is marked on the glass substrate that is 1 cm near side than the surface to be measured 21, and the spot is focused by the autofocus of the imaging device. Light is illuminated on the surface to be measured of the glass substrate, from the light source, via the mask, and the image of the reflected light on the surface to be measured of the glass substrate is photographed with the imaging device.

For the image photographed with the imaging device, noise is canceled by obtaining the moving average of 50 pixels in height and width, and digitalizing by regarding the maximum value/1.3 as a threshold. The left edge cell of each row is linear approximated by the least squares method, and the image is rotated so that the slope of the approximate line is 0, thereby correcting the position of the image.

Also, from the center of the image photographed with the camera, 1100 pixels are cut in the longitudinal direction (D1) of the liner bright region of the reflected light, and 500 pixels are cut in the transverse direction (D2) of the liner bright region of the reflected light.

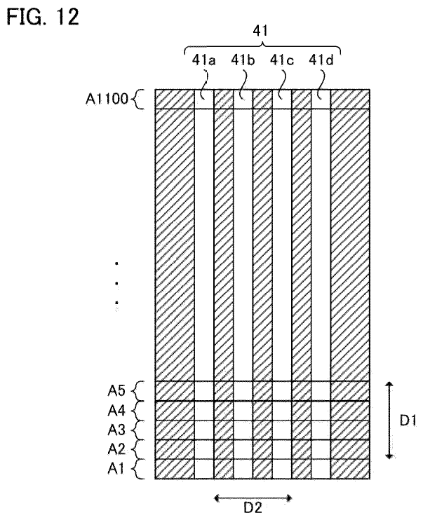

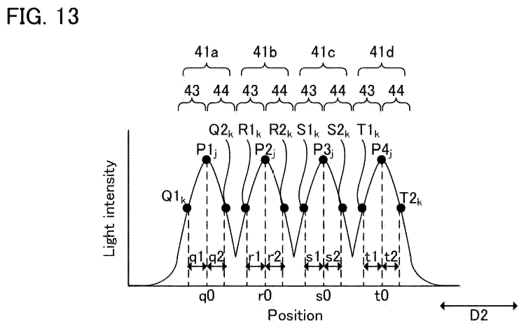

As shown in FIG. 12, the image is divided into 1100 segment regions in the longitudinal direction (D1) of the linear bright region of the reflected light. FIG. 13 is a graph showing the light intensity distribution of the reflected light in each segment region A1 to A1100. The light intensity is the average value of the luminance values of 8-bit 256 gradations of RGB.

As shown in FIG. 12, since the reflected light L2 includes four linear bright regions 41 (41a to 41d) corresponding to the linear bright region and the dark region of the illumination light L1, in the light intensity distribution of the reflected light shown in FIG. 13, the positions q0, r0, s0, t0 indicating the peak positions P1ⱼ to P4ⱼ of the light intensity are firstly determined per linear bright region 41a to 41d. Also, the light intensity distribution in each linear bright region 41a to 41d is divided into the left-side light intensity distribution 43 and the right-side light intensity distribution 44, with respective peak values P1ⱼ to P4ⱼ of the light intensity as the boundary. Then, in the left-side light intensity distribution 43 of the linear bright region 41a, the light intensity value Q1ₖ of the position, that is a predetermined value q1 (=20 pixels) away from the position q0 indicating the peak value P15 of the light intensity, is determined. Similarly, in the right-side light intensity distribution 44 of the linear bright region 41a, the light intensity value Q2ₖ of the position, that is a predetermined value q2 (=20 pixels) away from the position q0 indicating the peak value P1ⱼ of the light intensity, is determined. Then, per linear bright region 41a to 41d and per left-side light intensity distribution 43 and right-side light intensity distribution 44, the light intensity values Q1ₖ to Q2ₖ, R1ₖ to R2ₖ, S1ₖ to S2ₖ, T1ₖ to T2ₖ, of the positions, that is a predetermined values q1 to q2, r1 to r2, s1 to s2, t1 to t2 away from the positions q0, r0, s0, t0 indicating the peak values P1ⱼ to P4ⱼ of the light intensity, are determined. Further, per segment region A1 to A1100, per linear bright region 41a to 41d, and per left-side light intensity distribution 43 and right-side light intensity distribution 44, the light intensity values Q1ₖ to Q2ₖ, R1ₖ to R2ₖ, S1ₖ to S2ₖ, T1ₖ to T2ₖ (k=1 to 1100) are determined.

In this case, a smoothing treatment is carried out to the light intensity distribution of the reflected light, on the surface to be measured, detected by the imaging device in advance, in order to determine the position of the peak value of the light intensity in the bright region. Specifically, for the light intensity distribution in each segment region, a moving average of 50 pixels is determined, and the position of the maximum value of the light intensity in the linear bright region in the light intensity distribution after the moving average processing is regarded as the position of the peak value of the light intensity in the linear bright region.

Incidentally, the position 20 pixels away from the position indicating the peak value of the light intensity is the position where the light intensity is approximately 50% of the reference value. The reference value is obtained by determining the peak value of the light intensity per segment region and per linear bright region in the reflected light image, and the arithmetic average value of the peak value of this light intensity is regarded as the reference value.

Then, for the left-side light intensity distribution 43 of one linear bright region 41a, the arithmetic average value and standard deviation of the value Q1ₖ (k=1 to 1100) of the light intensity in each segment region A1 to A1100 are determined, the variation coefficient is calculated by dividing the standard deviation by the arithmetic average value, and this variation coefficient is regarded as the variation coefficient of the light intensity of the left-side light intensity distribution 43 of the linear bright region 41a. Also, for the right-side light intensity distribution 44 of one linear bright region 41a, the arithmetic average value and standard deviation of the value Q2ₖ (k=1 to 1100) of the light intensity in each segment region A1 to A1100 are determined, the variation coefficient is calculated by dividing the standard deviation by the arithmetic average value, and this variation coefficient is regarded as the variation coefficient of the light intensity of the right-side light intensity distribution 44 of the linear bright region 41a. Similarly, for the left-side light intensity distribution 43 of another linear bright region 41b, the arithmetic average value and standard deviation of the value R1ₖ (k=1 to 1100) of the light intensity in each segment region A1 to A1100 are determined, the variation coefficient is calculated by dividing the standard deviation by the arithmetic average value, and this variation coefficient is regarded as the variation coefficient of the light intensity of the left-side light intensity distribution 43 of the linear bright region 41b. Also, for the right-side light intensity distribution 44 of the linear bright region 41b, the arithmetic average value and standard deviation of the value R2ₖ (k=1 to 1100) of the light intensity in each segment region A1 to A1100 are determined, the variation coefficient is calculated by dividing the standard deviation by the arithmetic average value, and this variation coefficient is regarded as the variation coefficient of the light intensity of the right-side light intensity distribution 44 of the linear bright region 41b.

Also, for the left-side light intensity distribution 43 of another linear bright region 41c, the arithmetic average value and standard deviation of the value S1ₖ (k=1 to 1100) of the light intensity in each segment region A1 to A1100 are determined, the variation coefficient is calculated by dividing the standard deviation by the arithmetic average value, and this variation coefficient is regarded as the variation coefficient of the light intensity of the left-side light intensity distribution 43 of the linear bright region 41c. Also, for the right-side light intensity distribution 44 of the linear bright region 41c, the arithmetic average value and standard deviation of the value S2ₖ (k=1 to 1100) of the light intensity in each segment region A1 to A1100 are determined, the variation coefficient is calculated by dividing the standard deviation by the arithmetic average value, and this variation coefficient is regarded as the variation coefficient of the light intensity of the right-side light intensity distribution 24 of the linear bright region 21c. Further, for the left-side light intensity distribution 43 of another linear bright region 41d, the arithmetic average value and standard deviation of the value T1ₖ (k=1 to 1100) of the light intensity in each segment region A1 to A1100 are determined, the variation coefficient is calculated by dividing the standard deviation by the arithmetic average value, and this variation coefficient is regarded as the variation coefficient of the light intensity of the left-side light intensity distribution 43 of the linear bright region 41d. Also, for the right-side light intensity distribution 44 of the linear bright region 41d, the arithmetic average value and standard deviation of the value T2ₖ (k=1 to 1100) of the light intensity in each segment region A1 to A1100 are determined, the variation coefficient is calculated by dividing the standard deviation by the arithmetic average value, and this variation coefficient is regarded as the variation coefficient of the light intensity of the right-side light intensity distribution 44 of the linear bright region 41d. Then, the arithmetic average value of the variation coefficient, of light intensity of the left-side light intensity distribution 43 and right-side light intensity distribution 44 in each linear bright region 41a to 41d, is calculated. This the arithmetic average value of the variation coefficient, of light intensity of the left-side light intensity distribution 43 and right-side light intensity distribution 44 in each linear bright region 41a to 41d, is regarded as the variation of the light intensity.

The glass substrate having the variation value of the light intensity may be obtained by, for example, decreasing the ratio (CS_{σ}/CSₐᵥ) of the standard deviation (CS_{σ}) of the surface compressive stress value with respect to the average value (CSₐᵥ) of the surface compressive stress value, that is, the variation coefficient, specifically, making the variation coefficient to be 0.090 or less, in the glass substrate, at least for the first surface. The method for making the variation coefficient to be 0.090 or less is similar to the method described in “A. Glass substrate (first embodiment)”.

2. Average Value Tₐᵥ of Thickness and Average CSₐᵥ of Surface Compressive Stress Value

The average value (Tₐᵥ) of the thickness of the glass substrate and the average value (CSₐᵥ) of the surface compressive stress value of the first surface in the present embodiment are similar to “A. Glass substrate (first embodiment)”.

Since the other constitution of the glass substrate in the present embodiment is similar to “A. Glass substrate (first embodiment)”, the description herein is omitted.

### C. Glass Substrate (Third Embodiment)

The glass substrate in the present embodiment comprise: a first surface, and a second surface facing the first surface, wherein the glass substrate is a chemically strengthened glass; an average value (Tₐᵥ) of a thickness of the glass substrate is 20 μm or more and 200 μm or less; at least for the first surface of the glass substrate, an average value (CSₐᵥ) of a surface compressive stress value is 400 MPa or more and 800 MPa or less; and a reflected image definition measured from a first surface side is 701 or more.

Since the image definition in the glass substrate in the present embodiment is high as a predetermined value or more, it has excellent glass texture. Further in the glass substrate in the present embodiment, since the chemically strengthened glass is used, and the average value (Tₐᵥ) of the thickness and the average value (CSₐᵥ) of a surface compressive stress value of at least for the first surface are in the predetermined range, bending resistance may be improved.

### 1. Image Definition

The image definition indicates a degree of how clear is the reflected image of the surface to be measured can be seen without distortion, and the higher this value, the better the glass texture. The image definition is preferably 75% or more.

### [Method for Measuring Image Definition]

The method for measuring an image definition of the glass substrate in the present embodiment is as follows.

(1) Using a light source, illuminate an illumination light, including four linear bright regions and dark regions, on a surface to be measured that is the first surface of the glass substrate.

(2) Focusing on the light source via the surface to be measured with an imaging device, reflect the illumination light on the surface to be measured; receive reflected light including four linear bright regions and the dark regions corresponding to the bright regions and the dark regions of the illumination light; and detect a light intensity distribution of the reflected light on the surface to be measured.

(3) Divide the light intensity distribution of the reflected light, on the surface to be measured, into 1,100 segment regions in a direction corresponding to the longitudinal direction of the bright region of the illumination light; extract the light intensity distribution of the reflected light per segment region; determine the maximum value of the light intensity in the bright region, and the minimum value of the light intensity in the dark region, in the light intensity distribution of the reflected light on each segment region; calculate the image definition of each segment region by the following formula (1); and obtain an arithmetic average value.

$$DOI = ( M - m ) / ( M + m ) \times 100 \qquad ( 1 )$$

(In the above formula, DOI is the image definition, “M” is the maximum value of the light intensity in the bright region in the light intensity distribution of the reflected light on one segment region, and “m” is the minimum value of the light intensity in the dark region.)

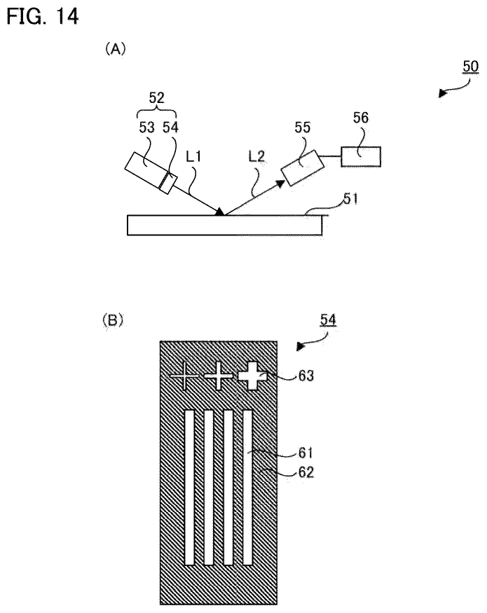

Specifically, the surface property measurement device 50 shown in FIG. 14(A) is used. The surface property measurement device 50 includes a light source 53, and includes an illuminating portion 52 configured to illuminate an illumination light, including four linear bright regions and dark regions, on a surface to be measured 51; an imaging device 55, focusing on the light source 53 via the surface to be measured 51, configured to reflect the illumination light on the surface to be measured 51, receive reflected light including four linear bright regions and dark regions corresponding to the bright regions and the dark regions of the illumination light, and detect a light intensity distribution of the reflected light on the surface to be measured; a processing portion 56 configure to determine the maximum value of the light intensity in the bright region, and the minimum value of the light intensity in the dark region, in the light intensity distribution of the reflected light on the surface to be measured, and calculate the image definition by the formula (1).

The illuminating portion 52 is one wherein a mask 54 including a metal plate 62 and rectangular openings 61 and cross-shaped openings 63 those pass through the metal plate 62 shown in FIG. 14(B), is directly adhered to the OL ED light source 53 described below. The mask includes transmission regions consisted from four rectangular openings 61 and transmission regions consisted from three cross-shaped openings, as shown in FIG. 14(B). The rectangular transmission region has a length of 70 mm, a line width of 0.5 mm, and a pitch of 1.0 mm. The distance between the light source 53 and the surface to be measured 51 of the glass substrate is 33 cm, and the incident angle of the illumination light emitted from the illuminating portion is 60°. Also, the distance between the imaging device 55 and the surface to be measured 51 is 33 cm, and the light receiving angle of the reflected light of the imaging device 55 is 60°. When the light from the LED light source passes through the mask 54, illumination light L1 including linear bright regions and dark regions is illuminated on the surface to be measured 21.

EELM-Sky-300-W from Ecorica Inc. is used as the LED light source, and a digital single-lens reflex camera D5600 from Nikon Corporation is used as the imaging device. For the lens, AF-P DX NIKKOR 18-55 mm f/3.5-5.6G VR from Nikon Corporation is used. The camera settings are set to an aperture of f/22, an exposure time of ⅛ seconds, ISO-100, and a focal length of 55 mm.

The camera is focused by an autofocus on the cross-shaped portion of the reflected image on the surface to be measured. Light is illuminated on the surface to be measured, from the light source, via the mask, and the image of the reflected light on the surface to be measured is photographed with the camera.

For the image photographed with the camera, noise is removed by obtaining the moving average of 50 pixels in height and width, and digitalizing by regarding the maximum value/1.3 as a threshold. The left edge cell of each row is linear approximated by the least squares method, and the image is rotated so that the slope of the approximate line is 0, and thereby adjusting the angle of the image.

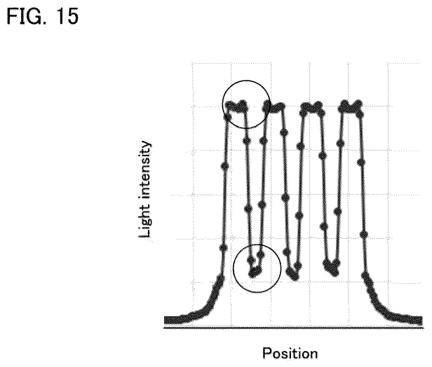

Also, from the center of the image photographed with the camera, 1100 pixels are cut in the direction corresponding to the longitudinal direction of the bright region of the illumination light, and 500 pixels are cut in the direction perpendicular to the longitudinal direction. The image definition of each segment region is obtained by dividing the image into 1,100 segment regions in the direction corresponding to a longitudinal direction of the bright region of the illumination light; extracting the light intensity distribution of the reflected light per segment region; determining the maximum value of the light intensity in the bright region, and the minimum value of the light intensity in the dark region, in the light intensity distribution of the reflected light on each segment region (FIG. 15); calculating the image definition of each segment region by the above formula (1); and obtaining an arithmetic average value.

For example, the glass substrate having the image definition described above can be obtained by decreasing the ratio (CS_{σ}/CSₐᵥ) of the standard deviation (CS_{σ}) of the surface compressive stress value with respect to the average value (CSₐᵥ) of the surface compressive stress value, that is, the variation coefficient, in the glass substrate, specifically, making the variation coefficient to be 0.090 or less. The method for making the variation coefficient to be 0.090 or less is similar to the method described in “A. Glass substrate (first embodiment)”.

2. Average Value Tₐᵥ of Thickness and Average Value CSₐᵥ of Surface Compressive Stress Value

The average value (Tₐᵥ) of the thickness of the glass substrate and the average value (CSₐᵥ) of the surface compressive stress value of the first surface in the present embodiment are similar to “A. Glass substrate (first embodiment)”.

Since the other constitution of the glass substrate in the present embodiment is similar to “A. Glass substrate (first embodiment)”, the description herein is omitted.

### D. Glass Stacked Body (First Embodiment)

The glass stacked body in the present embodiment comprises the glass substrate described above, and a resin layer disposed on at least one of a first surface side and a second surface side of the glass substrate.

FIG. 8(A) is a schematic cross-sectional view exemplifying a glass stacked body in the present embodiment. As shown in FIG. 8(A), the glass stacked body 10 includes the glass substrate 1 described above, and a resin layer 11 disposed on the first surface 1A side of the glass substrate 1.

FIG. 8(B) is a schematic cross-sectional view showing another example of a glass stacked body in the present embodiment. As shown in FIG. 8(B), the glass stacked body 10, includes the glass substrate 1 described above, and a resin layer 11 disposed on the first surface 1A side of the glass substrate 1, and a resin layer 12 disposed on the second surface 1B side of the glass substrate 1.

Since the glass substrate described above is included in the glass stacked body in the present embodiment, bending resistance may be improved. Also, it has excellent glass texture.

In the glass stacked body in the present embodiment, since the resin layer is disposed on at least one of the first surface side and the second surface side of the glass substrate, when an impact is imparted to the glass stacked body, the impact is absorbed by the resin layer so that the glass substrate is suppressed from being cracked, and the impact resistance may be improved. Further, the resin layer can suppress the scattering of glass, even if the glass substrate is broken.

Therefore, in the present embodiment, it is possible to obtained a glass stacked body with excellent bending resistance and excellent impact resistance. Further, even when the glass substrate in the glass stacked body is damaged, the risk of injury to the human body may be reduced, making it a highly safe glass stacked body. Thus, the glass stacked body in the present embodiment may be folded so that it may be used for a wide variety of display devices, for example, it may be used as a member for a foldable display.

Each constitution of the glass stacked body in the present embodiment is hereinafter described.

### 1. Glass Substrate

Since the glass substrate in the glass stacked body of the present embodiment is similar to those described in the sections “A. Glass substrate (first embodiment), “B. Glass substrate (second embodiment), or “C. Glass substrate (third embodiment), the explanation herein is omitted.

### 2. Resin Layer

The resin layer in the present embodiment is a layer disposed on at least one of a first surface side and a second surface side of the glass substrate. The resin layer can also function as an impact absorbing layer having impact absorbing properties, and as a scattering prevention layer that suppresses the scattering of glass when the glass substrate is broken.

Incidentally, in the present specification, when the glass stacked body in the present embodiment is used for a display device, the resin layer disposed on the observer side than the glass substrate may be called a front surface side resin layer, and a resin layer disposed on the surface of the glass substrate that is opposite side to the front surface side resin layer may be referred to as a rear surface side resin layer in some cases.

### (1) Material of Resin Layer

### (a) Resin

The resin included in the resin layer is not particularly limited if it is resin capable of obtaining a resin layer having transparency and impact absorbing properties. Specific examples may include polyimide based resins, polyester based resins, cellulose based resins, cyclo-olefin polymer (COP), epoxy resins, polyurethane, acrylic based resins, cyclo-olefins (COP) and polycarbonates (PC). One type of these resins may be used alone, and two types or more may be used in a combination.

Incidentally, in the present descriptions, polyimide based resin refers to a polymer including an imide bond in the main chain. Examples of the polyimide based resin may include polyimide, polyamideimide, polyesterimide, and polyetherimide. Examples of the polyester based resin may include polyethylene terephthalate (PET), polypropylene terephthalate, polybutylene terephthalate, and polyethylene naphthalate (PEN). Examples of the cellulose based resin may include triacetylcellulose (TAC). Examples of the acrylic based resin may include poly(meth)methyl acrylate, and poly(meth)ethyl acrylate. Among them, from the viewpoint of having bending resistance, excellent hardness and transparency, the polyimide based resin is preferable.

### (b) Additives

The resin layer may further include an additive if necessary. Examples of the additives may include ultraviolet ray absorbers, light stabilizers, antioxidants, inorganic particles, silica fillers for facilitating winding, surfactants for improving film forming property and antifoaming property, and close adhesiveness improving agents.

When the resin layer includes an ultraviolet ray absorber, the deterioration of the resin layer due to ultraviolet rays may be suppressed. In particular, when the resin layer includes polyimide, color change over time of the resin layer including polyimide may be suppressed. Also, in display device including a glass stacked body, the deterioration of a member disposed on the display panel side than the glass stacked body, such as a polarizer, due to ultraviolet rays may be suppressed.

Examples of the ultraviolet ray absorber included in the resin layer may include triazine based ultraviolet ray absorbers; benzophenone based ultraviolet ray absorbers such as hydroxybenzophenone based ultraviolet ray absorbers; and benzotriazole based ultraviolet ray absorbers.

Specific examples of the triazine based ultraviolet ray absorbers; benzophenone based ultraviolet ray absorbers such as hydroxybenzophenone based ultraviolet ray absorbers; and benzotriazole based ultraviolet ray absorbers may include those described in, for example, Japanese Patent Application Laid-Open (JP-A) No. 2019-132930.

Also, the ultraviolet ray absorber is preferably a polymer or oligomer. This is because the bleed-out of the ultraviolet ray absorber, when the glass stacked body is bent repeatedly, may be suppressed. Examples of such ultraviolet ray absorber may include polymers or oligomers including a triazine skeleton, a benzophenone skeleton, or a benzotriazole skeleton; and specifically, it is preferably ones obtained by thermally copolymerizing methyl methacrylate (MMA), and (meth)acrylate including a benzotriazole skeleton or a benzophenone skeleton at an arbitrary ratio.

The content of the ultraviolet ray absorber in the resin layer is not particularly limited, and is preferably, for example 1% by mass or more and 6% by mass or less, and more preferably 2% by mass or more and 5% by mass or less. When the content of the ultraviolet ray absorber is too low, the effect due to the ultraviolet ray absorber may not be sufficiently obtained. Also, when the content of the ultraviolet ray absorber is too high, the resin layer may be notably colored, or the hardness of the resin layer may decrease.

### (2) Thickness of Resin Layer

The thickness of the resin layer is not particularly limited as long as it has a thickness capable of having flexibility and impact absorbing properties, and the lower limit is preferably, for example, 10 μm or more, and more preferably 15 μm or more. Meanwhile, the upper limit is preferably 100 μm or less, more preferably 50 μm or less, and further preferably 40 μm or less. As for the specifical range, it is preferably 10 μm or more and 100 μm or less, more preferably 10 μm or more and 50 μm or less, and further preferably 15 μm or more and 40 μm or less. When the thickness of the resin layer is relatively thin as in the range described above, flexibility can be increased, and the resin layer can be suppressed from being cracked when the glass stacked body is bent, and the bending resistance can be maintained.

Here, the thickness of the resin layer may be an average value of the thickness of arbitrary 10 points obtained by measuring from the thickness directional cross-section of the glass stacked body by observing with a scanning electron microscope (SEM). Incidentally, the same may be applied to the measuring methods of the thickness of other layers included in the glass stacked body, unless otherwise stated.

The thickness of the resin layer is measured using a Scanning Electron Microscope (SEM) S-4800 from Hitachi High-Tech Corporation, under the following conditions.
Acceleration voltage: 3.0 kV
Emission current: 10 μA
Magnification: 500-fold

Using epoxy resin as a cold embedding resin, a sample is prepared by embedding a glass substrate into the epoxy resin, finishing it using Tegrapol-35 from Struers LLC as a mechanical polishing device, and subjecting to a platinum sputtering treatment.

### (3) Method for Forming Resin Layer

Examples of a method for forming a resin layer may include a method wherein the glass substrate is coated with a resin composition. The method for applying is not particularly limited as long as it is capable of applying with a desired thickness, and examples thereof may include general coating methods such as a gravure coating method, a gravure reverse coating method, a gravure offset coating method, a spin coating method, a roll coating method, a reverse roll coating method, a blade coating method, a dip coating method, and a screen printing method. Also, the resin layer can be formed by a transfer method wherein a resin layer is transferred to one surface of a glass substrate; or a method wherein a film-shaped resin layer is adhered to one surface of a glass substrate via an adhesive layer.

The adhesive layer has transparency. Specifically, the total light transmittance of the adhesive layer is preferably 85% or more, more preferably 88% or more, and further preferably 90% or more.

Examples of the adhesive used for the adhesive layer may include pressure-sensitive adhesives such as optically clear adhesive (OCA); heat-sensitive adhesives such as heat sealants; and curable type adhesives. One type of these may be used alone, and two types or more may be used in a combination.

The thickness of the adhesive layer is preferably, for example, 1 μm or more and 100 μm or less. When the thickness of the adhesive layer is too thick, the bending resistance may be deteriorated. Meanwhile, when the thickness of the adhesive layer is too thin, the adhesiveness may not be secured so as to be peeled off.

### 3. Functional Layer

The glass stacked body in the present embodiment may further include a functional layer on the surface of the surface side resin layer that is opposite to the glass substrate.

Examples of the functional layer may include a hard coating layer, a protective layer, an antireflection layer, and an antiglare layer. Also, the functional layer may be a single layer, and may include a plurality of layers. Also, the functional layer may be a layer having a single function, and may include a plurality of layers having functions different from each other. The glass stacked body in the present embodiment may include, for example, a hard coating layer and a protective layer, in this order from the resin layer side, as the functional layer.

The hard coating layer is a member to improve the surface hardness. By placing the hard coating layer, scratch resistance may be improved. Here, “hard coating layer” is a member configured to increase the surface hardness. Specifically, in a configuration wherein the glass stacked body in the present embodiment includes a hard coating layer, “hard coating layer” is referred to one exhibiting a hardness of “H” or more in the pencil hardness test according to JIS K 5600-5-4 (1999).

As a material of the hard coating layer, for example, an organic material, an inorganic material, and an organic-inorganic composite material may be used. Among the above, the material of the hard coating layer is preferably an organic material. Specifically, the hard coating layer preferably include a cured product of a resin composition including a polymerizable compound. The cured product of a resin composition including a polymerizable compound may be obtained by carrying out a polymerization reaction of a polymerizable compound, by a known method using a polymerization initiator if necessary.

The glass stacked body in the present embodiment may further include a protective layer on the surface of the surface side resin layer that is opposite to the glass substrate. The protective layer has transparency. Specifically, the total light transmittance of the protective layer is preferably 85% or more, more preferably 88% or more, and further preferably 90% or more.

The protective layer is not particularly limited as long as it has transparency; and, for example, it may include resin. The resin included in the protective layer is not particularly limited if it is resin capable of obtaining a protective layer having transparency, and commonly used resins may be used.

Examples of the method for placing a protective layer on a resin layer may include a method wherein a protective film is used as a protective layer, and the protective film is adhered to the resin layer via an adhesive layer; or a method wherein a protective layer is formed on the resin layer.

### 4. Other Constitution

In addition to the respective layers described above, the glass stacked body in the present disclosure may include other layers as required. Examples of the other layer may include a primer layer, and a decorative layer.

### 5. Properties of Glass Stacked Body

The total light transmittance of the glass stacked body in the present embodiment is preferably, for example, 80% or more, more preferably 85% or more, and further preferably 88% or more. When the total light transmittance is high as described above, the glass stacked body may have good transparency.

Here, the total light transmittance of the glass stacked body may be measured according to JIS K7361-L, and may be measure with, for example, a haze meter HM150 from Murakami Color Research Laboratory Co., Ltd.

The haze of the glass stacked body in the present embodiment is preferably, for example, 2.0% or less, more preferably 1.5% or less, and further preferably 1.0% or less. When the haze is low as described above, the glass stacked body may have good transparency.

Here, the haze of the glass stacked body may be measured according to JIS K-7136, and may be measure with, for example, a haze meter HM150 from Murakami Color Research Laboratory Co., Ltd.

The glass stacked body in the present embodiment preferably has a bending resistance. Specifically, when the U-shape bending test described above is carried out to the glass stacked body, the distance between the facing short side portions of the glass stacked body, when a crack or a fracture occurs in the glass stacked body may be 10 mm or less, preferably 5 mm or less, and particularly preferably 3 mm or less.

In the U-shape bending test, when the resin layer is disposed only on either one of the first surface side and the second surface side of the glass substrate, the glass stacked body may be folded so that the glass substrate is on the outer side, or the glass stacked body may be folded so that the glass substrate is on the inner side; and in either of these cases, it is preferable to have the bending resistance described above.

Also, when the dynamic bending test described above is carried out to the glass stacked body, it is preferable that a crack or a fracture does not occur in the glass stacked body when the glass stacked body is folded, so that the distance between the facing short side portions of the glass stacked body is 10 mm, repeatedly for 200,000 times.

### 6. Use Application of Glass Stacked Body

The glass stacked body in the present embodiment may be used as a member disposed on the observer side than the display panel in a display device. The glass stacked body in the present embodiment may be used for a display device used for an electronic device such as smart phones, tablet terminals, wearable terminals, personal computers, televisions, digital signages, public information displays (PIDs), and car mounted displays. Among them, the glass stacked body in the present embodiment may be preferably used for a flexible display such as a foldable display, a rollable display, and a bendable display; and more preferably used for a foldable display.

When the glass stacked body of the present embodiment is disposed on the surface of a display device, when the resin layer is disposed only on either one of the first surface side and the second surface side of the glass substrate, the glass stacked body may be disposed so that the glass substrate side surface is on the display panel side and the resin layer side surface is on the outer side; and the glass stacked body may be disposed so that the resin layer side surface is on the display panel side and the glass substrate side surface is on the outer side.

The method for disposing the glass stacked body in the present embodiment on the surface of a display device is not particularly limited, and examples thereof may include a method via an adhesive layer. As an adhesive layer, a known adhesive layer used for adhering a glass stacked body may be used.

### E. Glass Stacked Body (Second Embodiment)

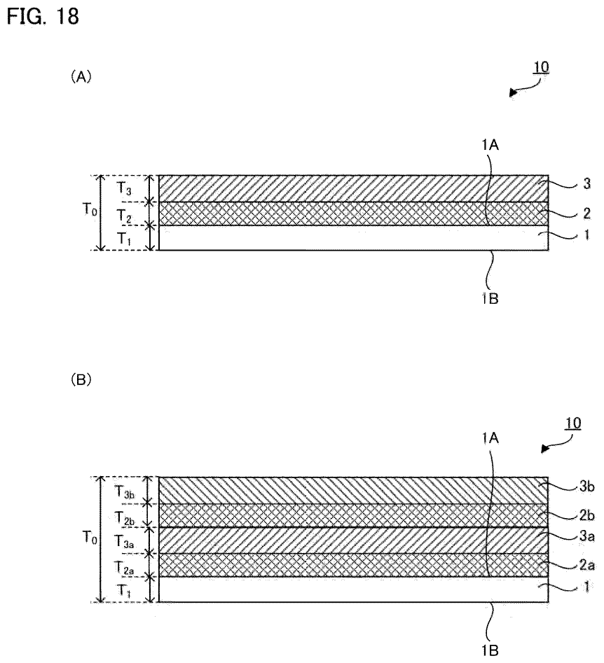

FIG. 18 are schematic cross-sectional views exemplifying a glass stacked body in the present embodiment. The glass stacked body 10 shown in FIG. 18(A) comprises a glass substrate 1 including a first surface 1A, and a second surface 1B facing the first surface; one joining layer 2 disposed on the first surface 1A side of the glass substrate 1; and one resin layer 3, wherein the thickness T₂ of the joining layer 2, with respect to the thickness T₀ of the glass stacked body 10, is 25V or less. The thickness T₀ of the glass stacked body 10 corresponds to the sum of the thickness T₁ of the glass substrate 1, the thickness T₂ of the joining layer 2, and the thickness T₃ of the resin layer 3.

The glass substrate 1 is a chemically strengthened glass; the thickness Tt is 20 μm or more and 200 μm or less; at least for the first surface 1A, the average value (CSₐᵥ) of a surface compressive stress value is 400 MPa or more and 800 MPa or less; and the ratio (CS_{σ}/CSₐᵥ) of a standard deviation (CS_{σ}) of the surface compressive stress value with respect to the average value (CSₐᵥ) of the surface compressive stress value is 0.090 or less. Further, the thickness T₀ of the glass stacked body 10 is 50 μm or more and 300 μm or less.

Also, the glass stacked body in the present embodiment may include two or more resin layers on the first surface side of the glass substrate 1. FIG. 18(B) is a schematic cross-sectional view showing another example of the glass stacked body in the present embodiment. The glass stacked body 10 shown in FIG. 18(B) includes two joining layers 2 (a first joining layer 2a and a second joining layer 2b) disposed on the first surface 1A side of the glass substrate 1, and two resin layers 3 (a first resin layer 3a and a second resin layer 3b), and they are disposed in the order of the first joining layer 2a, first resin layer 3a, second joining layer 2b, and second resin layer 3b from the glass substrate 1 side.

In this case, the thickness T₀ of the glass stacked body corresponds to the sum of the thickness T₁ of the glass substrate 1, the total thickness T₂ of the joining layers 2 (thickness T₂ₐ of the first joining layer+thickness T_{2b} of the second joining layer), and the total thickness T₃ of the resin layers 3 (thickness T₃ₐ of the first resin layer+thickness T_{3b} of the second resin layer). The total thickness T₂ of the joining layers 2 (thickness T₂ₐ of the first joining layer+thickness T_{2b} of the second joining layer) is 25% or less, with respect to the thickness T₀ of the glass stacked body 10.

Since the glass stacked body in the present embodiment includes the glass substrate that is a chemically strengthened glass, and having a thin thickness in the predetermined range, the bending resistance may be improved.

Also, the bending resistance can be further improved by setting the average value (CSₐᵥ) of the surface compressive stress value of at least for the first surface of the glass substrate to a predetermined range.

FIG. 2 and FIG. 3 show concept images of the surface compressive stress and tensile stress applied to the glass substrate. As shown in FIG. 2(A), FIG. 3(A), the chemically strengthened glass is a glass wherein mechanical properties are strengthened by a chemical method by partially exchanging, for example, a sodium ion with a potassium ion, in the vicinity of the surface of glass, and a compressive stress layer exists on the surface, and a tensile stress layer exists inside thereof. As shown in FIG. 2(A), the glass substrate whose surface compressive stress value is too low will break due to the tensile stress generated at the bent portion during bending, resulting in cracking (FIG. 2(B)). Also, as shown in FIG. 3(A), the glass substrate whose surface compressive stress value is too high will break from inside due to the influence of tensile strength inside the glass substrate and the tensile stress generated during bending, resulting in cracking (FIG. 3(B)).

In contrast to this, the bending resistance can be further improved and a breakage during bending may be suppressed, since the average value (CSₐᵥ) of the surface compressive stress value of at least for the first surface of the glass substrate, included in the glass stacked body of the present embodiment, is in a predetermined range.

Further, the inventors found out that when the degree of variation in the surface compressive stress value of the glass substrate is small, the glass texture is improved. The reason therefore is presumed as follows.

As described above, the chemically strengthened glass includes a compressive stress layer on the surface of the first surface and the second surface. In other words, the chemically strengthened glass is a glass wherein much potassium is present on its surface, and compressive stress is applied to its surface. The inventors have found out that the deterioration of the glass texture is due to a locally different refractive index of the glass substrate due to the uneven distribution of potassium. Further, based on the knowledge that the unevenness of the potassium distribution is correlated with the variation of the surface compressive stress value, the inventors have found out that when the degree of variation in the surface compressive stress value is small, the glass texture is improved.

FIG. 4 and FIG. 5 show concept images of the potassium ion distribution of the surface of the glass substrate, and graphs of the concentration distribution of the potassium ion by an energy dispersive X-ray analysis (EDX). As shown in FIGS. 5, when potassium is distributed unevenly on the surface of the glass substrate, it is inferred that the glass texture deteriorates since the refractive index of the glass substrate differs locally. Meanwhile, when the potassium is uniformly distributed as shown in FIGS. 4, it is inferred that the glass texture improves since the refractive index is not locally varied.

Further, the inventors have found out that the degree of variation in the surface compressive stress value can be evaluated accurately so that the glass texture is securely improved by using the ratio (CS_{σ}/CSₐᵥ) of the standard deviation (CS_{σ}) of the surface compressive stress value with respect to the average value (CSₐᵥ) of the surface compressive stress value of the glass substrate, that is, the variation coefficient, as a parameter for accurately evaluating the variation in the surface compressive stress value.

Also, since the thickness of the glass stacked body in the present embodiment is in a predetermined range, it has excellent impact resistance and excellent glass texture.

Further, the inventors of the present invention have found out that further excellent glass texture can be obtained by setting the total thickness of the joining layer disposed on the first surface side of the glass substrate, with respect to the thickness of the glass stacked body, to a predetermined ratio or less.

Therefore, in the present embodiment, it is possible to obtained a glass stacked body with excellent bending resistance and excellent impact resistance and glass texture. Thus, the glass stacked body in the present embodiment may be folded so that it may be used for a wide variety of display devices, for example, it may be used as a member for a foldable display. The glass stacked body in the present embodiment is hereinafter described in detail.

### 1. Glass Substrate

The glass substrate in the present embodiment comprises a first surface and a second surface facing the first surface. The first surface is the surface on which the joining layer and the resin layer are formed. When the glass stacked body in the present embodiment is disposed on the surface of a display device, it is preferably disposed so that the second surface of the glass substrate is on the display panel side, and the first surface of the glass substrate is on the outer side (observer side).

### (1) Thickness T₁

The lower limit of thickness T₁ of the glass substrate in the present embodiment is 20 μm or more, preferably 25 μm or more, and further preferably 30 μm or more. Meanwhile, the upper limit is 200 μm or less, and preferably 150 μm or less. The specific range is 20 μm or more and 200 μm or less, preferably 25 μm or more and 200 μm or less, and further preferably 30 μm or more and 150 μm or less. When the thickness of the glass substrate is thin as in the above range, excellent flexibility may be obtained, and at the same time, sufficient hardness may be obtained so as to be excellent in bending resistance. It is also possible to suppress curling of the glass substrate. Further, it is preferable in terms of reducing the weight of the glass substrate. The thickness of the glass substrate above refers to the distance between the first surface and the second surface of the glass substrate. The thickness of the glass substrate is obtained by measuring the thickness at multiple points (such as 5 points or more and 15 points or less) of the glass substrate, and determining the average value (Tₐᵥ) of the obtained thickness at the multiple points.

Since the average value (Tₐᵥ) of the thickness of the glass substrate is similar to the contents in “A. Glass substrate (first embodiment), 3. Thickness T, (1) Average value (Tₐᵥ)”, the explanation herein is omitted.

In the present embodiment, the lower limit value of the ratio (T_{σ}/Tₐᵥ) of the standard deviation (T_{σ}) of the thickness with respect to the thickness (that is, average value Tₐᵥ) of the glass substrate, that is, the variation coefficient is preferably 0.003 or more, and further preferably 0.005 or more. Meanwhile, the upper limit value is preferably 0.050 or less, and further preferably 0.03 or less. As for the specific range, it is preferably 0.003 or more and 0.050 or less, and further preferably 0.005 or more and 0.03 or less.

When T_{σ}/Tₐᵥ is too low, the close adhesiveness between the resin layer and the glass substrate may be poor. When T_{σ}/Tₐᵥ is too high, the glass texture of the glass substrate may deteriorate.

### (2) Surface Compressive Stress Value CS

In the glass substrate in the present embodiment, at least for the first surface, the average value (CSₐᵥ) of the surface compressive stress value is 400 MPa or more and 800 MPa or less. In particular, the average value (CSₐᵥ) of the surface compressive stress value of the both surfaces of the first surface and the second surface are preferably 400 MPa or more and 800 MPa or less.

Since the description about the surface compressive stress value CS is similar to “(1) Average value (CSₐᵥ)”, “(2) CS_{σ}/CSₐᵥ” and “(3) Method for adjusting” described in “A. Glass substrate (first embodiment), 2. Surface compressive stress value CS” above, the explanation herein is omitted.

### (3) Chemically Strengthened Glass

The glass substrate in the present embodiment is chemically strengthened glass. As described above, the chemically strengthened glass has better impact resistance and bending resistance compared to non-strengthened glass. Also, the chemically strengthened glass has excellent mechanical strength and exhibits an effect that it may be made thin accordingly.

Since the description about “Chemically strengthened glass” in the present embodiment is similar to the description in “A. Glass substrate (first embodiment), 1. Chemically strengthened glass”, the explanation herein is omitted.

### (4) Depth DOL of Compressive Stress Layer and Internal Tensile Stress CT

Since the description about “Depth DOL of compressive stress layer” and “Internal tensile stress CT” in the present embodiment is similar to the description in “(1) Depth DOL of compressive stress layer” and “(2) Internal tensile stress CT” described in “A. Glass substrate (first embodiment), 4. Others”, the explanation herein is omitted.

### (5) Glass Texture

The glass substrate in the present embodiment has excellent glass texture. Particularly, in the state of glass substrate, the variation value of the light intensity measured, from the first surface side, by the method for measuring surface properties described below may be as low as 6.5% or less. Also, the image definition calculated from the light intensity distribution of the reflected light may be high as 70% or more.

The variation value of the light intensity of the glass substrate, image definition, and method for measuring may be similar to the methods described in “G. Glass stacked body (fourth embodiment)” and “H. Glass stacked body (fifth embodiment)” described below, setting the first surface of the glass substrate as the surface to be measured.

### 2. Joining Layer

The glass stacked body in the present embodiment includes one or more joining layers on the first surface side of the glass substrate. When the thickness of the joining layer disposed on the first surface side of the glass substrate, the glass texture is deteriorated. When the thickness of the joining layer is a predetermined ratio or less, the deterioration of the glass texture may be suppressed. The joining layer is a layer configured to adhere between the glass substrate and the resin layer, or between the resin layers.

### (1) Thickness

In the present embodiment, one or more joining layers are included on the first surface side of the glass substrate. The total thickness T₂ of the joining layers, with respect to the thickness T₀ of the glass stacked body, is 25% or less. When the total thickness of the joining layers is too thick, the surface of the resin layer formed on the joining layer will be distorted and the glass texture of the glass stacked body is deteriorated. The total thickness T₂ of the joining layers, with respect to the thickness Tc of the glass stacked body, is preferably 20% or less, and further preferably 15% or less. Incidentally, when the glass stacked body includes one joining layer, as described above, the total thickness T2 of the joining layers refers to the thickness of that joining layer, and when the glass stacked body includes two or more joining layers, it refers to the total thickness of the two or more joining layers.

As for the specific total thickness T2 of the joining layers, the lower limit is, for example, more than 0 μm, and preferably 5 μm or more. Meanwhile, the upper limit is 30 μm or less, and preferably 20 μm or less. The specific range is more than 0 μm and 30 μm or less, and preferably 5 μm or more and 20 μm or less.

Also, when two or more joining layers are included, the lower limit of the thickness of each joining layer is, for example, more than 0 μm, and preferably 5 μm or more. Meanwhile, the upper limit is 30 μm or less, preferably 20 μm or less, and further preferably 15 μm or less. The specific range is more than 0 μm and 30 μm or less, preferably 5 μm or more and 20 μm or less, and further preferably 5 μm or more and 15 μm or less.

The thickness of the joining layer is measured using a Scanning Electron Microscope (SEM) S-4800 from Hitachi High-Tech Corporation, under the following conditions.
Acceleration voltage: 3.0 kV
Emission current: 10 μA
Magnification: 500-fold

Using epoxy resin as a cold embedding resin, a sample is prepared by embedding a glass substrate into the epoxy resin, finishing it using Tegrapol-35 from Struers LLC as a mechanical polishing device, and subjecting to a platinum sputtering treatment.

The joining layer has transparency. Specifically, the total light transmittance of the joining layer is preferably 85% or more, more preferably 88% or more, and further preferably 90% or more.

### (2) Material

The material used for the joining layer is not particularly limited as long as it is a material capable of joining the glass substrates and the resin layer, and examples thereof may include pressure-sensitive adhesives such as optically clear adhesive (OCA); heat-sensitive adhesives such as heat sealants; and curable type adhesives. One type of these may be used alone, and two types or more may be used in a combination.

Examples of the pressure-sensitive adhesives such as optically clear adhesive (OCA) may include acrylic based tackiness agents, urethane based tackiness agents, silicone based tackiness agents, epoxy based tackiness agents, vinyl acetate based tackiness agents, and polyvinyl acetal based tackiness agents such as polyvinyl butyral (PVB).

For example, thermally weldable thermoplastic resins may be used as the heat-sensitive adhesives such as heat sealants. Such thermoplastic resins are not particularly limited, and examples thereof may include acrylic resins, vinyl chloride-vinyl acetate copolymers, polyamide resins, polyester resins, polyester urethane resins, chlorinated polypropylenes, chlorinated rubbers, urethane resins, epoxy resins, styrene resins, polyolefin resins, silicone resins, polyvinyl acetal resins such as polyvinyl butyral (PVB), and polyether urethane resins. One type of these thermoplastic resins may be used alone, and two types or more may be used in a combination.

Also, the heat-sensitive adhesive composition may further include a curing agent. Thereby, heat resistance and close adhesiveness may be improved. Also, by adding the curing agent, the composite elastic modulus of the joining layer, which will be discussed later, may be adjusted. In order to obtain a joining layer with a desired composite elastic modulus, it is preferable to add the curing agent as appropriate, for example, according to the properties of the thermoplastic resin. Examples of the curing agent may include isocyanate based curing agents, epoxy based curing agents, and melamine based curing agents. One type of the curing agents may be used alone, and two types or more may be used in a combination. When the heat-sensitive adhesive composition includes a curing agent, the joining layer will include the cured product of the heat-sensitive adhesive composition.

Also, the heat-sensitive adhesive composition may include additives if necessary. Examples of the additives may include a light stabilizer, ultraviolet ray absorbers, infrared absorbers, antioxidants, plasticizers, coupling agents, antifoaming agents, fillers, inorganic or organic particles configured to adjust the refractive index, antistatic agents, coloring agents such as a blue pigment and a violet pigments, a leveling agent, a surfactant, an easy lubricant, various sensitizers, a flame retardant, an adhesive imparting agent, a polymerization inhibitor, and a surface modifier.

Examples of the curable type adhesive may include thermosetting type adhesives and ultraviolet ray curable type adhesives. The thermosetting adhesive is an adhesive cured by heat. Examples of the thermosetting adhesives may include epoxy based adhesives, acrylic based adhesives, urethane based adhesives, polyester based adhesives, and silicone based adhesives. The ultraviolet ray curable type adhesive is an adhesive cured by irradiation of ultraviolet rays. Examples of the ultraviolet ray curable type adhesives may include epoxy based adhesives, acrylic based adhesives, and urethane, acrylate based adhesive.

Also, the curable type adhesive composition may include additives if necessary. Examples of the additives may include a light stabilizer, ultraviolet ray absorbers, infrared absorbers, antioxidants, plasticizers, coupling agents, antifoaming agents, fillers, inorganic or organic particles configured to adjust the refractive index, antistatic agents, coloring agents such as a blue pigment and a violet pigments, a leveling agent, a surfactant, an easy lubricant, various sensitizers, a flame retardant, an adhesive imparting agent, a polymerization inhibitor, and a surface modifier. These additives may be selected and used as appropriate from those of regular use. The content of the additive may be set accordingly.

Among the above, the material used for the joining layer is preferably a heat-sensitive adhesive or a curable type adhesive, and more preferably a heat sealant, ultraviolet ray curable type adhesive, or thermosetting type adhesive.

Also, the joining layer preferably includes at least one type selected from a group consisting of polyester resin, polyolefin resin, polyolefin resin, and urethane resin. Among them, the joining layer more preferably includes polyester resin. Incidentally, the urethane resin includes polyester urethane resin and polyether urethane resin. For the joining layer including such a material, it is easier to adjust the composite elastic modulus described below to the preferable range.

The composite elastic modulus of the joining layer is preferably, for example, 1 MPa or more, more preferably 10 MPa or more, and further preferably 20 MPa or more. Since the composite elastic modulus of the joining layer is in the above range, and by having a certain level of hardness, the surface hardness of the hard coating film side surface of the stacked body may be increased, and the scratch resistance may be improved, as well as the impact resistance may be improved. Meanwhile, the composite elastic modulus of the joining layer is preferably, for example, less than 5400 MPa, more preferably 5000 MPa or less, and further preferably 4500 MPa or less. When the composite elastic modulus of the joining layer is too high, the adhesiveness may be decreased, or the hardness may be too high to bend, resulting in reduced bending resistance, especially dynamic bending property. The composite elastic modulus of the joining layer is preferably, for example, 1 MPa or more and less than 5400 MPa, more preferably 10 MPa or more and 5000 MPa or less, further preferably 20 MPa or more and 4500 MPa or less, and particularly preferably 25 MPa or more and 4000 MPa or less. The method for measuring the composite elastic modulus of the joining layer may be similar to the method for measuring the composite elastic modulus of the resin layer described below.

Further, the higher the glass transition point (Tg) of the resin used for the joining layer, the better. This is because the lower the Tg, the higher the flowability of the joining layer when joining the glass and resin, so that orange peel is hardly caused. Incidentally, when the Tg is too high, the flowability may be deteriorated, sufficient close adhesiveness may not be obtained.

The lower limit of the Tg of the resin used for the joining layer is preferably −20° C. or more, particularly −10° C. or more, and above all, 0° C. or more. Meanwhile, the upper limit of the Tg is usually 100° C. or less.

Here, the glass transition temperature Tg of the joining layer means a value measured by a method based on the peak top value of loss tangent (tan δ) (DMA method). When the storage elastic modulus E′, loss elastic modulus E″, and loss tangent tan δ of the heat-sensitive layer is measured with the dynamic mechanical analyzing device (DMA), firstly, the joining layer is punched into a size of 15 mm×200 mm. In this process, a test piece of the joining layer may be obtained by preparing a solution by dissolving the material of the joining layer or melting the material of the joining layer; coating a substrate with the solution; drying; and then, peeling the film from the substrate. The solvent is appropriately selected according to the material of the joining layer, and examples thereof may include ethyl acetate. Also, when preparing the solution, the material of the joining layer may be heated and dissolved as appropriate. For example, a Naflon (registered trademark) sheet from Nichias Corporation (300 mm×300 mm×1 mm thickness) may be used as the substrate. The joining layer is then sampled so as to be a cylindrical shape of approximately φ 5 mm×5 mm in height. At this time, the joining layer may be wound to make it cylindrical. The cylindrical measurement sample is installed between the compression jigs (parallel plate (8 mm) of the dynamic mechanical analyzing device. Then, the dynamic mechanical analysis is carried out in the range of −50° C. or more and 200° C. or less, applying a compressive load and imparting a longitudinal vibration at frequency of 1 Hz, and a storage elastic modulus E′, a loss elastic modulus E″ and loss tangent tan δ of the joining layer at respective temperature are measured. The glass transition temperature of the junction layer is the temperature at which the loss tangent tan δ peaks in the range of −50° C. or more and 200° C. or less. For example, RSA III from TA Instruments may be used as a dynamic mechanical analyzing device. Incidentally, the specific measurement conditions in the above method are shown below.

### (Measurement Conditions of Glass Transition Temperature)

Measurement sample: cylindrical shape of ϕ5 mm×height 5 mm
Measuring jig: compression (parallel plate)
Measurement mode: temperature dependence (temperature range: −50° C. to 200° C., temperature rising rate: 5° C./min)
Frequency: 1 Hz

### 3. Resin Layer

The glass stacked body in the present embodiment includes one or more resin layers on the first surface side of the glass substrate. The resin layer can also function as an impact absorbing layer having impact absorbing properties, and as a scattering prevention layer that suppresses the scattering of glass when the glass substrate is broken. By placing the resin layer on the first surface side of the glass substrate, when an impact is imparted to the glass stacked body, the impact is absorbed by the resin layer so that the glass substrate is suppressed from being cracked, and the impact resistance may be improved. Further, the resin layer can suppress the scattering of glass, even if the glass substrate is broken.

Further, since the resin layer in the present embodiment is formed on the joining layer with a predetermined thickness or less, distortion on the surface of the resin layer is suppressed, resulting in a glass stacked body with a good glass texture.

### (1) Thickness of Resin Layer

As for the total thickness of the resin layer, the lower limit is preferably, for example, 10 μm or more, and more preferably 15 μm or more. Meanwhile, the upper limit is preferably 100 μm or less, more preferably 70 μm or less, and further preferably 60 μm or less. As for the specifical range, it is preferably 10 μm or more and 100 μm or less, more preferably 10 μm or more and 70 μm or less, and further preferably 15 μm or more and 60 μm or less. When the total thickness of the resin layer is the above value or less, flexibility can be increased, and the resin layer can be suppressed from being cracked when the glass stacked body is bent, and the bending resistance can be maintained. Also, when the total thickness of the resin layer is the above value or more, impact absorbing properties can be reliably obtained.

Here, the total thickness of the resin layer may be an average value of the thickness of arbitrary 10 points obtained by measuring from the thickness directional cross-section of the glass stacked body by observing with a scanning electron microscope (SEM). Incidentally, the same may be applied to the measuring methods of the thickness of other layers included in the glass stacked body, unless otherwise stated.

The total thickness of the resin layer is measured using a Scanning Electron Microscope (SEM) S-4800 from Hitachi High-Tech Corporation, under the following conditions.
Acceleration voltage: 3.0 kV
Emission current: 10 μA
Magnification: 500-fold

Using epoxy resin as a cold embedding resin, a sample is prepared by embedding a glass substrate into the epoxy resin, finishing it using Tegrapol-35 from Struers LLC as a mechanical polishing device, and subjecting to a platinum sputtering treatment.

Also, when the glass stacked body includes one resin layer, the total thickness T3 of the resin layer refers to the thickness of that resin layer, and when the glass stacked body includes two or more resin layers, it refers to the total thickness of the two or more resin layers.

Also, when the glass stacked body of the present embodiment includes two or more resin layers, the lower limit of the thickness of each resin layer is, for example, 5 μm or more, and preferably 25 μm or more. Meanwhile, the upper limit is 80 μm or less, and preferably 55 μm or less. The specific range is 5 μm or more and 80 μm or less, and preferably 25 μm or more and 55 μm or less.

### (2) Material of Resin Layer

The material used for the resin layer is similar to those described in “D. Glass tacked body (First embodiment), 2. Resin layer, (1) Material of resin layer”, and the explanation is omitted herein.

### (3) Specific Embodiments of Resin Layer

Each resin layer included in the glass stacked body is not particularly limited if it has impact resistance, and it may be a single layer including the resin material, and a hard coating film including a resin substrate including the resin material and a hard coating layer formed on one surface of the resin substrate, can be used. The hard coating layer is a member configured to improve the surface hardness. By disposing the hard coating layer, scratch resistance may be improved.

As for the thickness of the resin substrate included in the hard coating film, the lower limit is preferably, for example, 10 μm or more, and more preferably 15 μm or more. Meanwhile, the upper limit is preferably 100 μm or less, more preferably 70 μm or less, and further preferably 60 μm or less. As for the specifical range, it is preferably 10 μm or more and 100 μm or less, more preferably 10 μm or more and 70 μm or less, and further preferably 15 μm or more and 60 μm or less.

The “hard coating layer” is a member configured to increase the surface hardness. Specifically, in a configuration wherein the glass stacked body in the present embodiment includes a hard coating layer, “hard coating layer” is referred to one having a hardness of “H” or more in the pencil hardness test according to JIS K 5600-5-4 (1999).

When the glass stacked body in the present disclosure includes the hard coating layer on the surface of the resin substrate that is opposite to the glass substrate, the pencil hardness of the hard coating layer side surface of the glass stacked body is preferably H or more, more preferably 2H or more, and further preferably 3H or more.

Here, the pencil hardness is measured by the pencil hardness test specified by JIS K5600-5-4 (1999). Specifically, using a pencil for the test according to JIS-S-6006, the pencil hardness test according to JIS K5600-5-4 (1999) is carried out to the hard coating layer side surface of the glass stacked body, and the pencil hardness may be determined by evaluating the highest pencil hardness at which the sample is not bruised. The measurement conditions may be angle of 45°, load of 750 g, speed of 0.5 mm/sec or more and 1 mm/sec or less, and temperature of 23±2° C. As the pencil hardness tester, for example, a pencil scratch hardness tester from Toyo Seiki Seisaku-sho, Ltd. may be used.

The hard coating layer may be a single layer, and may have a multi-layered structure of two layers or more. When the hard coating layer has the multi-layered structure, in order to improve the surface hardness, and also to improve the balance of bending resistance and elastic modulus, the hard coating layer preferably includes a layer configured to satisfy the pencil hardness and a layer configured to satisfy the dynamic bending test (a layer configured to satisfy the chafing resistance).

As a material of the hard coating layer, for example, an organic material, an inorganic material, and an organic-inorganic composite material nay be used.

Among the above, the material of the hard coating layer is preferably an organic material. Specifically, the hard coating layer preferably include a cured product of a resin composition including a polymerizable compound. The cured product of a resin composition including a polymerizable compound may be obtained by carrying out a polymerization reaction of a polymerizable compound, by a known method using a polymerization initiator if necessary.

The thickness of the hard coating layer included in the hard coating film is, for example, 1 μm or more, preferably 3 μm or more, more preferably 5 μm or more, and further preferably 10 μm or more. Since the thickness of the hard coating layer is in the above range, the surface hardness of the hard coating film side surface of the stacked body may be increased, and the scratch resistance may be improved. Meanwhile, the thickness of the hard coating layer is, for example, 30 μm or less, preferably 25 μm or less, and further preferably 20 μm or less. When the thickness of the hard coating layer is in the above range, better bending resistance may be obtained.

### (4) Composite Elastic Modulus of Resin Layer

The resin layer is not particularly limited as long as it has impact resistance. The composite elastic modulus of the resin layer is, for example, 5.4 GPa or more, preferably 5.7 GPa or more, more preferably 6.0 GPa or more, and particularly preferably 6.5 GPa or more. By setting the composite elastic modulus of the resin layer in the above range, a crack of the glass substrate due to an impact may be suppressed, and the impact resistance and scratch resistance may be improved, even when the thickness of the resin layer is relatively thin. Examples of the resin included in such resin layer may include polyimide, polyamideimide, acrylic resins, epoxy resins, urethane resins and triacetylcellulose (TAC).

Also, according to the method for measuring a composite elastic modulus described below, since the composite elastic modulus of the glass substrate is approximately 40 GPa, the composite elastic modulus of the resin layer is preferably, for example, 40 GPa or less, and more preferably 20 GPa or less.

Here, the composite elastic modulus of the resin layer is calculated using contact projection area Aₚ determined when measuring the indentation hardness (H_{IT}) of the resin layer. The “indentation hardness” is a value determined from a load-displacement curve from indenter loading to unloading obtained by a hardness measurement by the nanoindentation method. The composite elastic modulus of the resin layer is an elastic modulus including the elastic deformation of the resin layer and the elastic deformation of the indenter.

The measurement of the indentation hardness (H_{IT}) is carried out, to a measurement sample, using “TI950 TriboIndenter” from Bruker Corporation. Specifically, at first, a block wherein a glass stacked body cut out to a size of 1 mm×10 mm is embedded in an embedding resin is prepared, and a uniform section with a thickness of 50 nm or more and 100 nm or less without a hole, for example, is cut out from this block by a common section preparing method. For the preparation of the section, for example, “Ultramicrotome EM UC7” (from Leica Microsystems, Inc.) may be used. Then, the remaining of the block from which this uniform section without a hole, for example, is cut out is used as a measurement sample. Then, onto the cross-section in such the measurement sample obtained by cutting out the section, a Berkovich indenter (a triangular pyramid, TI-0039 from Bruker Corporation) as the indenter is compressed perpendicularly onto the center of the cross-section of the resin layer, under the following conditions, taking 10 seconds, until the maximum compressing load of 25 μN. Here, in order to avoid an influence of the glass substrate, and in order to avoid an influence of the side edge of the resin layer, the Berkovich indenter shall be compressed into a portion of the resin layer which is 500 nm away from the interface between the glass substrate and the resin layer toward the center side of the resin layer, and 500 nm away from both side edges of the resin layer respectively toward the center side of the resin layer. Incidentally, when an optional layer exists on the surface of the resin layer that is opposite to the glass substrate side, the Berkovich indenter shall be compressed into a portion of the resin layer which is also 500 nm away from the interface between the optional layer and the resin layer toward the center side of the resin layer. Then, after relieving the remaining stress by maintaining constant, the load was unloaded in 10 seconds, the maximum load after relieving was measured, and by using the maximum load Pₘₐₓ (μN) and the contact projection area Aₚ (nm²), the indentation hardness (H_{IT}) is calculated by Pₘₐₓ/Aₚ. The contact projection area is a contact projection area wherein the indenter tip curvature is corrected by Oliver-Pharr method, using a reference sample fused quartz (5-0098 from Bruker Corporation). The indentation hardness (H_{IT}) is an arithmetic average value of the value obtained by measuring at ten places. Incidentally, when a value deviating ±20% or more from the arithmetic average value is included in the measured value, that measured value is excluded, and the measurement is carried out for one more time. Whether the value deviating ±20% or more from the arithmetic average value exists in the measured value, or not is determined by finding out whether the value (%) obtained by (A−B)/B×100, when the measured value is regarded as A and the arithmetic average value is regarded as B, is ±20% or more, or not. The indentation hardness (H_{IT}) can be adjusted with the type of the resin included in the resin layer described below.

Also, when the resin layer is a hard coating film including a resin substrate and a hard coating layer described above, the resin substrate preferably has the composite elastic modulus in the above range.

### (Measurement Conditions)

Loading speed: 2.5 μN/second
Retention time: 5 seconds
Unloading speed: 2.5 μN/second
Measuring temperature: 25° C.

The composite elastic modulus Eᵣ of the resin layer is determined from the following mathematical formula (1), using contact projection area Aₚ obtained when measuring the indentation hardness. As for the composite elastic modulus, the indentation hardness is measured at 10 places, determining the composite elastic modulus each time, and the arithmetic average value of the obtained composite elastic modulus of 10 places is regarded as the composite elastic modulus.

$$[ Mathematic 2 ]$$

$${E}_{r} = \frac{S \sqrt{π}}{2 \sqrt{{A}_{p}}} \qquad ( 1 )$$

(In the mathematic formula (1), Aₚ is a contact projection area, Eᵣ is the composite elastic modulus of the resin layer, and S is a contact stiffness.)

### (5) Method for Forming Resin Layer

Examples of a method for forming a resin layer may include a method wherein a joining layer formed on the first surface side of the glass substrate or the first surface of the glass substrate is directly coated with a resin composition. The method for applying is not particularly limited as long as it is capable of applying with a desired thickness, and examples thereof may include general coating methods such as a gravure coating method, a gravure reverse coating method, a gravure offset coating method, a spin coating method, a roll coating method, a reverse roll coating method, a blade coating method, a dip coating method, and a screen printing method.

Also, the resin layer can be formed by a transfer method wherein a resin layer is transferred to the first surface of a glass substrate; or a method wherein a film-shaped resin layer is adhered to the first surface of a glass substrate via a joining layer.

### 4. Thickness

The thickness of the glass stacked body in the present embodiment is 50 μm or more and 300 μm or less. When the thickness of the glass stacked body is too thin, it is inferior in impact resistance. When the thickness of the glass stacked body is too thick, it may be inferior in glass texture. The lower limit of the thickness of the glass stacked body, is preferably 70 μm or more, and further preferably 100 μm or more. Meanwhile, the upper limit is preferably 270 μm or less, and more preferably 240 μm or less. The specific range is preferably 70 μm or more and 270 μm or less, and further preferably 100 μm or more and 240 μm or less.

### 5. Glass Texture

The glass stacked body in the present embodiment has excellent glass texture. Particularly, the variation value of the light intensity measured, from the resin layer side of the glass stacked body, by the predetermined method for measuring surface properties may be a predetermined value or less. Also, the image definition calculated from the light intensity distribution of the reflected light can be increased. Since the variation value of the light intensity, image definition, and method for measuring are similar to those described in “C. Glass stacked body (third embodiment)” and “D. Glass stacked body (fourth embodiment)” described below, the explanation herein is omitted.

### 6. Bending Resistance

The glass stacked body in the present embodiment preferably has a bending resistance. Specifically, the bending resistance of the glass stacked body can be evaluated by carrying out a U-shape bending test described below.

The U-shape bending test is carried out as follows. Firstly, a test piece, a glass stacked body having a size of 20 mm×100 mm, is prepared. Then, as shown in FIG. 6(a), a short side portion 10P and a short side portion 10Q facing the short side portion 10P of the glass stacked body 10 are respectively fixed by parallelly arranged fixing portions 100A, 100B. As shown in FIG. 6(a), the fixing portion 100B is movable by sliding in horizontal direction. Then, as shown in FIG. 6(b), by moving the fixing portion 100B so as to be closer to the fixing portion 100 A, the glass stacked body 10 is bent into a U-shape. Further, as shown in FIG. 6(c), by moving the fixing portion 100B, a distance “d” between the two facing short side portions 10P, 100 of the glass stacked body 10, fixed by the fixing portions 100A, 100B, is gradually reduced until a crack or a fracture occurs in the glass stacked body 10. In doing so, the bending test is carried out so that bent portion 10R of the glass stacked body 10 does not protrude from the lower end edge of the fixing portions 100A, 100B. For example, when the distance “d” between the two facing short side portions 10P and 100 is 10 mm, the outer diameter of the bent portion 10R is regarded as 10 mm.

In the U-shape bending test, the distance “d” between the facing short side portions 10P and 10Q of the glass stacked body 10, when a crack or a fracture occurs in the glass stacked body is preferably 10 mm or less, more preferably 7 mm or less, and particularly preferably 5 mm or less. Incidentally, the smaller the distance “d” between the facing short side portions 10P, 10Q of the glass stacked body 10, the higher the bending resistance.

In the U-shape bending test, the glass stacked body may be folded so that the glass substrate is on the outer side, or the glass stacked body may be folded so that the glass substrate is on the inner side; and in either of these cases, it is preferable to have the bending resistance described above.

Also, when the dynamic bending test described above is carried out to the glass stacked body, it is preferable that a crack or a fracture does not occur in the glass stacked body when the glass stacked body is folded, so that the distance between the facing short side portions of the glass stacked body is 10 nm, repeatedly for 200,000 times.

### 7. Other Properties of Glass Stacked Body

The total light transmittance and haze of the glass stacked body in the present embodiment are similar to the contents described in “D. Glass stacked body (First embodiment), 5. Properties of glass stacked body”, so the description herein is omitted.

### 8. Use Application

The glass stacked body in the present embodiment may be used for a member disposed on the observer side than the display panel in a display device, that is, for a member for a display device.

When disposed on the surface of a display device, the glass stacked body in the present embodiment is preferably disposed so that the glass substrate side surface is on the display panel side and the resin layer side surface is on the outer side.

The method for disposing the glass stacked body in the present embodiment on the surface of a display device is not particularly limited, and examples thereof may include a method via an adhesive layer. As an adhesive layer, a known adhesive layer used for adhering a glass stacked body may be used.

### F. Glass Stacked Body (Third Embodiment)

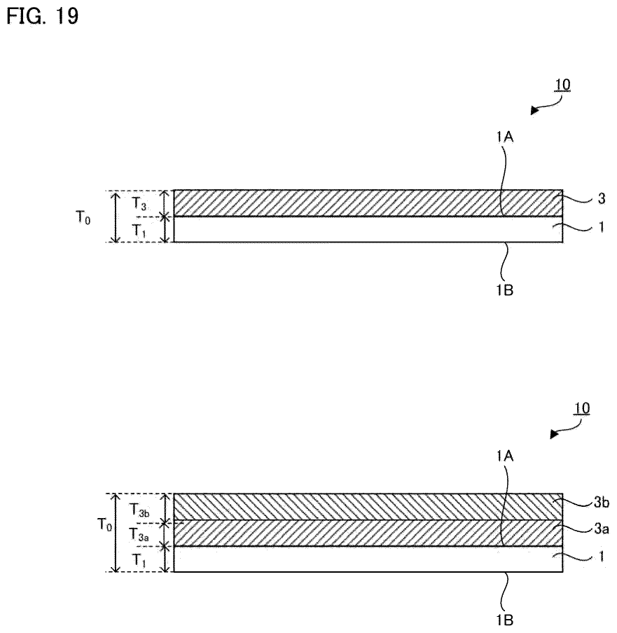

FIG. 19 are schematic cross-sectional views exemplifying a glass stacked body in the present embodiment. The glass stacked body 10 shown in FIG. 19(A) includes a glass substrate 1, and one resin layer 3 disposed on the first surface 1A side of the glass substrate 1, and the resin layer 3 is in contact with the glass substrate 1. Also, the glass stacked body 10 shown in FIG. 19(A) does not include a joining layer on the first surface 1A side of the glass substrate 1.

Also, the glass stacked body 10 shown in FIG. 19(B) includes two or more resin layers 3 (first resin layer 3a and second resin layer 3b) on the first surface side of the glass substrate 1, and the first resin layer 3a is in contact with the glass substrate 1. In this case, the thickness T₀ of the glass stacked body corresponds to the sum of the thickness T₁ of the glass substrate 1, and the total thickness T₃ of the resin layer 3 (the thickness T₃ₐ of the first resin layer+the thickness T_{3b} of the second resin layer).

The glass substrate 1 is a chemically strengthened glass; the thickness T₁ is 20 μm or more and 200 μm or less; at least for the first surface 1A, the average value (CSₐᵥ) of a surface compressive stress value is 400 MPa or more and 800 MPa or less; and the ratio (CS_{σ})/CSₐᵥ) of a standard deviation (CS_{σ}) of the surface compressive stress value with respect to the average value (CSₐᵥ) of the surface compressive stress value is 0.090 or less. Further, the thickness T₀ of the glass stacked body 10 is 50 μm or more and 300 μm or less.

The glass stacked body in the present embodiment has excellent bending resistance and impact resistance for the same reasons as in the first embodiment, and has excellent glass texture when observed from the resin layer side.

In particular, the glass stacked body in the present embodiment has further excellent glass texture since one resin layer is in contact with the glass substrate, preferably not including the joining layer on the first surface side of the glass substrate. Incidentally, in the present embodiment, “the resin layer is in contact with the glass substrate” means that the resin layer and the glass substrate are in contact without interposing the joining layer therebetween, and the presence of a primer layer between the resin layer and the glass substrate is not excluded.

Since the other constitution, properties and use application of the glass stacked body in the present embodiment are similar to “E. Glass stacked body (second embodiment), the description herein is omitted.

### G. Glass Stacked Body (Fourth Embodiment)

The glass stacked body in the present embodiment comprise: a glass substrate including a first surface, and a second surface facing the first surface; and a resin layer disposed on a first surface side of the glass substrate, wherein the glass substrate is a chemically strengthened glass, and a thickness of the glass substrate is 20 μm or more and 200 μm or less; at least for the first surface of the glass substrate, an average value (CSₐᵥ) of a surface compressive stress value is 400 MPa or more and 800 MPa or less; a thickness of the glass stacked body is 50 μm or more; and for the glass stacked body, a variation value of a light intensity measured, from a resin layer side, by the method for measuring surface properties described below is 10.5% or less.

In the glass stacked body in the present embodiment, since the variation value of the light intensity measured by the method for measuring surface properties described below is low as the predetermined value described above or less, it has excellent glass texture. Further, in the glass stacked body in the present embodiment, the bending resistance can be improved by setting the thickness in a predetermined range, and setting the average value (CSₐᵥ) of the surface compressive stress value of at least for the first surface in a predetermined range, and by using a glass substrate that is a chemically strengthened glass.

Further, since the thickness of the glass stacked body in the present embodiment is a predetermined value or more, it has excellent impact resistance.

### 1. Variation Value of Light Intensity

The variation value of the light intensity measured by using the method for measuring surface properties indicates the degree of variation of the light intensity due to surface properties such as convexoconcave and undulation of the surface of the glass stacked body, and the lower this value, the better the glass texture. The variation value of the light intensity measured, from the resin layer side of the glass stacked body in the present embodiment is preferably 9.0% or less.

Since the method for measuring surface properties is similar to the method described in “B. Glass substrate (second embodiment), 1. Variation value of light intensity”, the explanation herein is omitted.

Examples of the method for obtaining a glass stacked body having the variation value of the light intensity described above may include a method wherein a glass substrate having good glass texture is used. For example, it can be obtained by decreasing the ratio (CS_{σ}/CSₐᵥ) of the standard deviation (CS_{σ}) of the surface compressive stress value with respect to the average value (CSₐᵥ) of the surface compressive stress value, that is, the variation coefficient, specifically, making the variation coefficient to be 0.090 or less, in the glass substrate, at least for the first surface. The method for making the variation coefficient to be 0.090 or less is similar to the method described in “E. Glass stacked body (second embodiment), 1. Glass substrate”. Further, examples may include a method wherein the total thickness of the joining layer is reduced. Specifically, example may include a method wherein the total thickness T2 of the joining layers, with respect to the thickness T₀ of the glass stacked body, is set to 25% or less. Since the total thickness of the joining layers in this case is similar to “E. Glass stacked body (second embodiment), 2. Joining layer”, the description herein is omitted. Also, examples may include a method wherein the glass substrate and the resin layer of the glass stacked body are disposed so as to be in contact, not via the joining layer. Since the structure of the glass stacked body in this case is similar to “F. Glass stacked body (third embodiment)”, the description herein is omitted. Further, examples may include a method wherein the thickness of the glass stacked body is reduced. Specifically, the thickness of the glass stacked body may be 200 μm or less. Since the thickness of the glass stacked body in this case is similar to “E. Glass stacked body (second embodiment), 4. Thickness”, the description herein is omitted.

2. Thickness T₁ of Glass Substrate and Average Value CSₐᵥ of Surface Compressive Stress Value

The thickness of glass substrate and the average value (CSₐᵥ) of the surface compressive stress value of the first surface in the present embodiment are similar to “E. Glass stacked body (second embodiment), 1. Glass substrate”.

The other constitution, properties and use application of the glass stacked body in the present embodiment may be similar to “E. Glass stacked body (second embodiment)”.

### H. Glass Stacked Body (Fifth Embodiment)

The glass stacked body in the present embodiment comprise: a glass substrate including a first surface, and a second surface facing the first surface; and a resin layer disposed on a first surface side of the glass substrate, wherein the glass substrate is a chemically strengthened glass, and a thickness of the glass substrate is 20 μm or more and 200 μm or less; at least for the first surface of the glass substrate, an average value (CSₐᵥ) of a surface compressive stress value is 400 MPa or more and 800 MPa or less; a thickness of the glass stacked body is 50 μm or more; and a reflected image definition measured from a resin layer side is 65% or more.

Since the image definition of the glass stacked body in the present embodiment is high as a predetermined value or more, it has excellent glass texture. Further, in the glass stacked body in the present embodiment, the bending resistance can be improved by setting the thickness in a predetermined range, setting the average value (CSₐᵥ) of the surface compressive stress value of at least for the first surface in a predetermined range, and by using a glass substrate that is a chemically strengthened glass.

Further, since the thickness of the glass stacked body in the present embodiment is a predetermined value or more, it has excellent impact resistance.

### 1. Image Definition

The image definition indicates a degree of how clear is the reflected image of the surface to be measured seen without distortion, and the higher this value, the better the glass texture. The lower limit value of the image definition is 65% or more, and preferably 70% or more. Meanwhile, the upper limit value is 100% or less. The specific range is 65% or more and 100% or less, and preferably 70% or more and 100% or less.

Since the method for measuring an image definition is similar to the method described in “C. Glass substrate (third embodiment), 1. Image definition”, the explanation herein is omitted.

Examples of the method for obtaining a glass stacked body having the image definition described above may include a method wherein a glass substrate having good glass texture is used. For example, it can be obtained by decreasing the ratio (CS_{σ}/CSₐᵥ) of the standard deviation (CS_{σ}) of the surface compressive stress value with respect to the average value (CSₐᵥ) of the surface compressive stress value, that is, the variation coefficient, specifically, making the variation coefficient to be 0.090 or less, in the glass substrate, at least for the first surface. The method for making the variation coefficient of the surface compressive stress value of the glass substrate to be 0.090 or less is similar to the method described in “A. Glass stacked body (first embodiment), 1. Glass substrate”. Further, examples may include a method wherein the total thickness of the joining layer is reduced. Specifically, example may include a method wherein the total thickness T₂ of the joining layers, with respect to the thickness T₀ of the glass stacked body, is set to 25% or less. Since the total thickness of the joining layers in this case is similar to “E. Glass stacked body (second embodiment), 2. Joining layer”, the description herein is omitted. Also, examples may include a method wherein the glass substrate and the resin layer of the glass stacked body are disposed so as to be in contact, not via the joining layer. Since the structure of the glass stacked body in this case is similar to “F. Glass stacked body (third embodiment)”, the description herein is omitted. Further, examples may include a method wherein the thickness of the glass stacked body is reduced. Specifically, the thickness of the glass stacked body may be 200 μm or less. Since the thickness of the glass stacked body in this case is similar to “E. Glass stacked body (first embodiment), 4. Thickness”, the description herein is omitted.

2. Thickness T₁ of Glass Substrate and Average Value CSₐᵥ of Surface Compressive Stress Value

The thickness of glass substrate and the average value (CSₐᵥ) of the surface compressive stress value of the first surface in the present embodiment are similar to “E. Glass stacked body (second embodiment), 1. Glass substrate”.

Since the other constitution, properties and use application of the glass stacked body in the present embodiment are similar to “E. Glass stacked body (second embodiment)”, the description herein is omitted.

### I. Member for Display Device

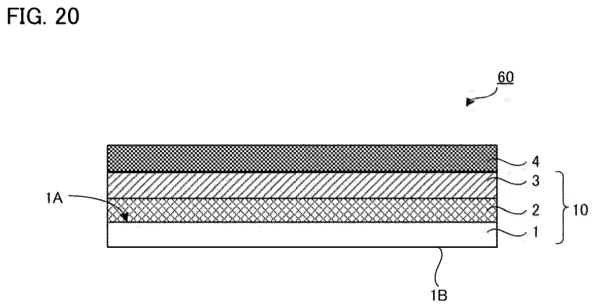

FIG. 20 is a schematic cross-sectional view exemplifying a member for a display device of the present disclosure.

The member for a display device 60 in the present disclosure comprises a glass stacked body 10, and a functional layer 4 disposed on a resin layer 3 side of the glass stacked body 10. Examples of the functional layer may include a protective layer, an antireflection layer, and an antiglare layer.

The functional layer may be a single layer, and may include a plurality of layers. Also, the functional layer may be a layer having a single function, and may include a plurality of layers having functions different from each other.

The member for a display device in the present disclosure may include a protective layer on the surface of the resin layer in the glass stacked body that is opposite to the glass substrate. The protective layer has transparency. Specifically, the total light transmittance of the protective layer is preferably 85% or more, more preferably 88% or more, and further preferably 90% or more.

The protective layer is not particularly limited as long as it has transparency; and, for example, it may include resin. The resin used for the protective layer is not particularly limited if it is resin capable of obtaining a protective layer having transparency, and commonly used resins may be used.

Examples of the method for disposing a protective layer on a resin layer may include a method wherein a protective film is used as a protective layer, and the protective film is adhered to the resin layer via an adhesive layer; or a method wherein a protective layer is formed on the resin layer.

The member for a display device in the present disclosure is a member disposed on the observer side than the display panel in a display device. The member for a display device in the present disclosure may be used for a display device used for an electronic device such as smart phones, tablet terminals, wearable terminals, personal computers, televisions, digital signages, public information displays (PIDs), and car mounted displays. Among the above, the glass stacked body in the present disclosure may be preferably used for a flexible display such as a foldable display, a rollable display, and a bendable display; and more preferably used for a foldable display.

In addition to the respective layers described above, the member for a display device in the present disclosure may include other layers as required. Examples of the other layer may include a primer layer, and a decorative layer.

Also, the member for a display device in the present disclosure may include a rear surface joining layer and a rear surface resin layer disposed on the surface of the glass stacked body that is opposite to the functional layer. The rear surface joining layer and the rear surface resin layer are disposed on the second surface side of the glass substrate, and ones similar to those described in “E. Glass stacked body (second embodiment), 2. Joining layer”, “E. Glass stacked body (second embodiment), 3. Resin layer” above may be used. Meanwhile, the rear surface joining layer is preferably thin since a distortion likely occurs on the resin layer (front surface resin layer) side surface of the glass stacked body, when the thickness of the rear surface joining layer is thick. The thickness of the rear surface joining layer is, for example, 3 μm or more and 100 μm or less, and preferably 5 μm or more and 50 μm or less.

### J. Display Device

The display device in the present disclosure comprises: a display panel, and the glass substrate described above, glass stacked body described above, or member for a display device described above disposed on an observer side of the display panel.

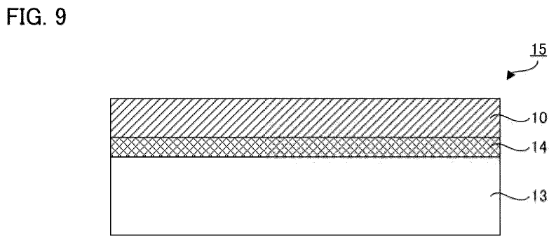

FIG. 9 is a schematic cross-sectional view exemplifying a display device in the present disclosure, and it is an example provided with the glass stacked body described above. As shown in FIG. 9, display device 15 comprises a display panel 13, and the glass stacked body 10 disposed on an observer side of the display panel 13. In the display device 15, the glass stacked body 10 is used as a member to be disposed on the surface of the display device 15, and an adhesive layer 14 is disposed between the glass stacked body 10 and the display panel 13.

The glass substrate, glass stacked body, and member for a display device in the present disclosure may be similar to the glass substrate, glass stacked body, and member for a display device described above.

Examples of the display panel in the present disclosure may include a display panel used for a display device such as a liquid crystal display device, an organic EL display device, and a LED display device.

The display device in the present disclosure may include a touch-sensitive panel member between the display panel and the glass substrate, glass stacked body or member for a display device.

The display device in the present disclosure is preferably a flexible display. Among them, the display device in the present disclosure is preferably foldable. That is, the display device in the present disclosure is more preferably a foldable display. Since the display device in the present disclosure includes the glass substrate or the glass stacked body described above, it has excellent impact resistance and bending resistance, and is suitable as a flexible display, and further a foldable display.

### K. Method for Inspecting Glass Substrate (First Embodiment)

As described above, when the thickness of the glass substrate, which is a chemically strengthened glass, is reduced, the visual texture peculiar to glass such as definition may be deteriorated, and there is a need for a method for quantitatively evaluating the glass texture.

The method for inspecting a glass substrate in the present embodiment is a method for inspecting a glass substrate including a first surface and a second surface facing the first surface, and the glass substrate is a chemically strengthened glass, the method comprises a step of selecting a glass substrate having a variation value of a light intensity measured, from a first surface side, by a following method for measuring surface properties of 6.5% or less.

With such a method for inspecting a glass substrate, the degree of variation of the light intensity due to surface properties such as convexoconcave and undulation of the surface of the glass substrate can be evaluated quantitatively. In other words, by evaluating a glass substrate having a variation value of the light intensity of a predetermined value or less as pass, evaluating a glass substrate having the value of more than the predetermined value as fail, and selecting a glass substrate having a variation value of the predetermined value or less, a glass substrate having excellent glass texture can be prepared. The selected glass substrate can be used, in particular, in the production of display devices.

Since the method for measuring surface properties is similar to the contents described in “B. Glass substrate (second embodiment)” above, the explanation herein is omitted.

### L. Method for Inspecting Glass Substrate (Second Embodiment)

The method for inspecting a glass substrate in the present embodiment is a method for inspecting a glass substrate including a first surface and a second surface facing the first surface, and the glass substrate is a chemically strengthened glass, the method comprises a step of selecting a glass substrate having a reflected image definition, measured from a first surface side, of 70% or more.

With such a method for inspecting a glass substrate, the degree of how clear is the reflected image of the glass substrate seen without distortion can be evaluated quantitatively. In other words, by evaluating a glass substrate having an image definition of a predetermined value or more as pass, evaluating a glass substrate having an image definition less than the predetermined value as fail, and selecting a glass substrate having an image definition of the predetermined value or more, a glass substrate having excellent glass texture can be prepared. The selected glass substrate can be used, in particular, in the production of display devices.

Since the method for measuring an image definition is similar to the contents described in “C. Glass substrate (third embodiment)” above, the explanation herein is omitted.

### M. Method for Inspecting Glass Stacked Body (First Embodiment)

As described above, when the thickness of the glass substrate, which is a chemically strengthened glass, is reduced, the visual texture peculiar to glass such as definition may be deteriorated, and there is a need for a method for quantitatively evaluating the glass texture of a glass stacked body.

The method for inspecting a glass stacked body in the present embodiment is a method for inspecting a glass stacked body including a glass substrate that is a chemically strengthened glass and including a first surface, and a second surface facing the first surface; and a resin layer disposed on a first surface side of the glass substrate, the method comprising a step of selecting a glass stacked body having a variation value of a light intensity measured from a resin layer side, by a following method for measuring surface properties of 10.5% or less.

With such a method for inspecting a glass stacked body, the degree of variation of the light intensity due to surface properties such as convexoconcave and undulation of the surface of the glass stacked body can be evaluated quantitatively. In other words, by evaluating a glass stacked body having a variation value of the light intensity of a predetermined value or less as pass, evaluating a glass stacked body having the value more than the predetermined value as fail, and selecting a glass stacked body having a variation value of the predetermined value or less, a glass stacked body having excellent glass texture can be prepared. The selected glass stacked body can be used, in particular, in the production of display devices.

Since the method for measuring surface properties is similar to the contents described in “G. Glass stacked body (fourth embodiment)” above, the explanation herein is omitted.

### N. Method for Inspecting Glass Stacked Body (Second Embodiment)

The method for inspecting a glass stacked body in the present embodiment is a method for inspecting a glass stacked body including a glass substrate that is a chemically strengthened glass and including a first surface, and a second surface facing the first surface; and a resin layer disposed on a first surface side of the glass substrate, the method comprising a step of selecting a glass stacked body having a reflected image definition, measured from a resin layer side, of 65% or more.

With such a method for inspecting a glass stacked body, the degree of how clear is the reflected image of the glass stacked body seen clearly without distortion can be evaluated quantitatively. In other words, by evaluating a glass stacked body having an image definition of a predetermined value or more as pass, evaluating a glass stacked body having an image definition of less than the predetermined value as fail, and selecting a glass stacked body having an image definition of the predetermined value or more, a glass substrate having excellent glass texture can be prepared. The selected glass stacked body can be used, in particular, in the production of display devices.

Since the method for measuring an image definition is similar to the contents described in “H. Glass stacked body (fifth embodiment)” above, the explanation herein is omitted.

### O. Method for Producing Display Device (First Embodiment)

The present embodiment provides a method for producing a display device, the method comprising a glass substrate inspecting step of carrying out the method for inspecting a glass substrate described above. In other words, in the method for producing a display device in the present embodiment, a display device is produced using the glass substrate selected by the method for inspecting a glass substrate described above. A resin layer is formed on the selected glass substrate as necessary, and is used as a member for a display device. The member for a display device may be used as a member disposed on the observer side than the display panel in a display device

The method for disposing the member for a display device on the surface of the display device in the present embodiment is not particularly limited, and examples thereof may include a method via an adhesive layer. As an adhesive layer, a known adhesive layer used for adhering a member for a display device may be used.

### P. Method for Producing Display Device (Second Embodiment)

The present embodiment provides a method for producing a display device, the method comprising a glass stacked body inspecting step of carrying out the method for inspecting a glass stacked body described above. In other words, in the method for producing a display device in the present embodiment, a display device is produced using the glass stacked body selected by the method for inspecting a glass substrate described above. The selected glass stacked body is used as a member for a display device. The member for a display device may be used as a member disposed on the observer side than the display panel in a display device.

Incidentally, the present disclosure is not limited to the embodiments. The embodiments are exemplification, and any other variations are intended to be included in the technical scope of the present disclosure if they have substantially the same constitution as the technical idea described in the claim of the present disclosure and offer similar operation and effect thereto.

### EXAMPLE

Hereinafter, the present disclosure will further be described by way of Examples and Comparative Examples.

### I. Examples Relating to Glass Substrate

### [Preparation of Glass Substrate]

### Examples I-1 to I-10, Comparative Examples I-1 to I-6

A glass substrate having the thickness (average value (Tₐᵥ), standard deviation (T_{σ}), and variation coefficient (Ta/Tₐᵥ)) shown in Table 1 was subjected to a chemically strengthening treatment, and a chemically strengthened glass having surface compressive stress (average value (CSₐᵥ), standard deviation (CS_{σ}), and variation coefficient (CS_{σ}/CSₐᵥ)) shown in Table 1 was obtained. Incidentally, average value (Tₐᵥ), standard deviation (T_{σ}), and variation coefficient (T_{σ}/Tₐᵥ) of the thickness, and average value (CSₐᵥ), standard deviation (CS_{σ}), and variation coefficient (CS_{σ}/CSₐᵥ) of the surface compressive stress value were measured as follows.

[Average Value (Tₐᵥ), Standard Deviation (T_{σ}), and Variation Coefficient (to/Tₐᵥ) of Thickness]

The average thickness (Tₐᵥ) of the glass substrate was obtained by preparing 9 areas by dividing the glass substrate into 3 respective areas in the first direction (x direction) and the second direction (y direction) perpendicular to the first direction, in a surface parallel to the first surface and the second surface; measuring the thickness at one point in each area; and determining the arithmetic average of the 9 measurement points. Further, the standard deviation (T_{σ}), and variation coefficient (To/Tₐᵥ) of these measured values were determined.

[Average Value (CSₐᵥ), Standard Deviation (CS_{σ}), and Variation Coefficient (CS_{σ}/CSₐᵥ) of Surface Compressive Stress Value]

For the glass substrate in Examples I-1 to I-10 and Comparative Examples I-1 to I-6, the average value (CSₐᵥ) of surface compressive stress value was obtained by preparing 9 areas by dividing the first surface of the glass substrate into 3 respective areas in the first direction (x direction) and the second direction (y direction) perpendicular to the first direction, in the surface; measuring the surface compressive stress value CS at one point in each area; and determining the arithmetic average of the 9 measurement points. A refractometer type glass surface stress meter FSM-6000LE from Iuceo co., Ltd. was used to measure the surface compressive stress CS. Further, the standard deviation (CS_{σ}), and variation coefficient (CS_{σ}/CSₐᵥ) of these measured values were determined. Incidentally, the measurement conditions (device design) of the FSM-6000LE were as follows.
Light source: 365 nm
Refractive index (prism): 1.756
Optical path length: 192.7 mm

### [Depth (DOL) of Compressive Stress Layer and Internal Tensile Stress (CT)]

For the glass substrate in Examples I-1 to I-10 and Comparative Examples I-1 to I-6, the average value of the depth (DOL) of the compressive stress layer and the average value of the internal tensile stress (CT) were measured, from the first surface, with a refractometer type glass surface stress meter FSM-6000LE from Iuceo co., Ltd. under the measurement conditions described above. These average values are the average values of DOL and CT at the nine measurement points described above.

### [Evaluation 1 Image Definition]

For the glass substrate in Examples I-1 to I-10 and Comparative Examples I-1 to I-6, the image definition was measured by the method described in “C. Glass substrate (third embodiment)” above. The results are shown in Table 1.

### [Evaluation 2 Variation Value of Light Intensity]

For the glass substrate in Examples I-1 to I-10 and Comparative Examples I-1 to I-6, the variation value of the light intensity was measured by the method described in “B. Glass substrate (second embodiment)” above. The results are shown in Table 1.

### [Evaluation 3 Visual Evaluation]

Using an LED light source, light was illuminated from the first surface side of the glass substrate in Examples I-1 to I-10 and Comparative Examples I-1 to I-6, reflected, visually observed from the first surface side, and evaluated under the following evaluation criteria. The results are shown in Table 1. The observations were carried out indoors (not in a darkroom).

### Evaluation Criteria

The visual observation was carried out by 20 people, and evaluated by the number of people who found no deformation nor unevenness.
A: 18 people or more
B: 10 people or more
C: 5 people or more
D: 4 people or less

### [Evaluation 4 U-Shaped Bending Test]

The U-shaped bending test described above was carried out to the glass substrate. The minimum value of the distance “d” (mm) between the two facing short side portions of the glass substrate, at which a crack or a fracture does not occur in the glass substrate was measured. The results are shown in Table 1.

### [Evaluation 5 Glass Floating Evaluation Test]

The glass substrate obtained above was cut into a size of 100 mm×100 mm, and this test piece was disposed on a horizontal base table for 5 minutes. The maximum distance of the gap (floating of the glass substrate) generated between the base table and the test piece was measured with a gap gauge (SUS plate). Also, the floating of the glass substrate when a test piece cut into a size of 320 mm×280 mm was used, was measured similarly. The results are shown in Table 1.

TABLE 1

| | | | | | | | | | | Variation | | | Floating of | |
|---|---|---|---|---|---|---|---|---|---|---|---|---|---|---|
| | | | | | | | | | | value of | | | glass substrate | |
| | | | | | | | | | Image | light | | Bending | [mm] | |
| | Tₐᵥ | T_{σ} | T_{σ}/ | CSₐᵥ | CS_{σ} | CS_{σ}/ | CT | DOL | definition | intensity | Visual | test | 100 × | 320 × |
| | [μm] | [μm] | Tₐᵥ | [MPa] | [MPa] | CSₐᵥ | [Mpa] | [μm] | [%] | [%] | Observation | [mm] | 100 | 280 |
| Ex. I-1 | 69 | 0.8 | 0.012 | 610 | 8.5 | 0.014 | 123 | 9.9 | 80.5 | 4.8 | A | 3.0 | <0.1 | 0.2 |
| Ex. I-2 | 51 | 1 | 0.020 | 580 | 10.6 | 0.018 | 210 | 10.7 | 80.9 | 4.9 | A | 2.0 | <0.1 | — |
| Ex. I-3 | 31 | 0.5 | 0.016 | 520 | 24.4 | 0.047 | 183 | 6.4 | 77.3 | 5.2 | B | 1.5 | 0.3 | — |
| Ex. I-4 | 31 | 0.4 | 0.013 | 530 | 35.2 | 0.066 | 186 | 6.4 | 73.3 | 5.3 | B | 1.5 | 0.5 | — |
| Ex. I-5 | 50 | 0.4 | 0.008 | 667 | 17.3 | 0.026 | 303 | 11.9 | 80.5 | 4.8 | A | 1.5 | 0.3 | — |
| Ex. I-6 | 52 | 0.5 | 0.010 | 786 | 36.1 | 0.046 | 191 | 8.5 | 80.2 | 4.9 | A | 4.0 | 0.2 | — |
| Ex. I-7 | 52 | 0.5 | 0.010 | 631 | 5.6 | 0.009 | 306 | 12.8 | 83.2 | 4.8 | A | 2.5 | <0.1 | — |
| Ex. I-8 | 105 | 0.4 | 0.004 | 650 | 5.8 | 0.009 | 132 | 15.2 | 84.0 | 4.4 | A | 4.0 | <0.1 | — |
| Ex. I-9 | 140 | 0.6 | 0.004 | 640 | 4.5 | 0.007 | 107 | 17.5 | 84.2 | 4.2 | A | 6.0 | <0.1 | — |
| Ex. I-10 | 30 | 1 | 0.033 | 560 | 38 | 0.068 | 197 | 6.2 | 72.1 | 6.0 | B | 1.5 | 0.5 | — |
| Comp. Ex. I-1 | 52 | 3.3 | 0.063 | 850 | 90.3 | 0.106 | 55 | 3.0 | 65.2 | 6.6 | C | 5.0 | 1.5 | — |
| Comp. Ex. I-2 | 59 | 4.6 | 0.078 | 923 | 96.7 | 0.105 | 90 | 4.8 | 63.5 | 7.1 | C | 7.0 | 1.0 | — |
| Comp. Ex. I-3 | 70 | 1.6 | 0.023 | 599 | 56.0 | 0.093 | 164 | 12.4 | 68.9 | 6.8 | C | 4.0 | — | 4.5 |
| Comp. Ex. I-4 | 70 | 0.7 | 0.010 | 932 | 8.2 | 0.009 | 186 | 10.0 | 80.2 | 5.0 | A | 8.0 | <0.1 | — |
| Comp. Ex. I-5 | 70 | 0.7 | 0.010 | 868 | 8.2 | 0.009 | 256 | 13.0 | 80.4 | 5.2 | A | 7.0 | <0.1 | — |
| Comp. Ex. I-6 | 70 | 0.8 | 0.011 | 350 | 7.3 | 0.021 | 61 | 9.0 | 80.2 | 5.1 | A | 7.0 | <0.1 | — |

As shown in Table 1, there was a correlation between the evaluation results of visual tests and image definition. Also, there was a correlation between the evaluation result of the visual test and the variation value of the light intensity.

As shown in Examples I-1 to I-10 in Table 1, when the average value (Tₐᵥ) of the thickness of the glass substrate was 20 μm or more and 200 μm or less, and when the average value (CSₐᵥ) of a surface compressive stress value was 400 MPa or more and 800 MPa or less, it was confirmed that the bending resistance was excellent (specifically, the minimum value of the distance “d” of 6 mm or less).

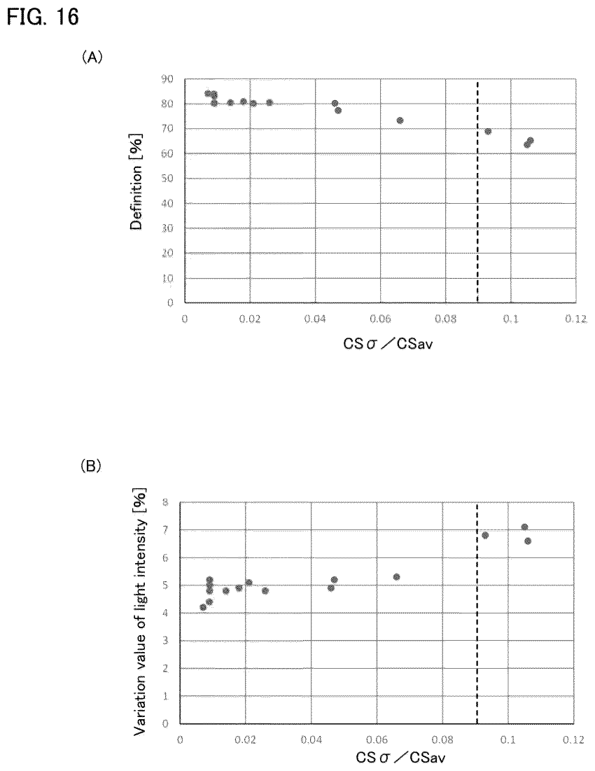

For the glass substrate in Examples I-1 to I-10 and Comparative Examples I-1 to I-6, the relation between the variation coefficient (CS_{σ}/CSₐᵥ) of surface compressive stress value (horizontal axis) and the image definition (vertical axis) is shown in FIG. 16(A). The relation between the variation coefficient (CS_{σ}/CSₐᵥ) of surface compressive stress value (horizontal axis) and the variation value of the light intensity (vertical axis) is shown in FIG. 16(B).

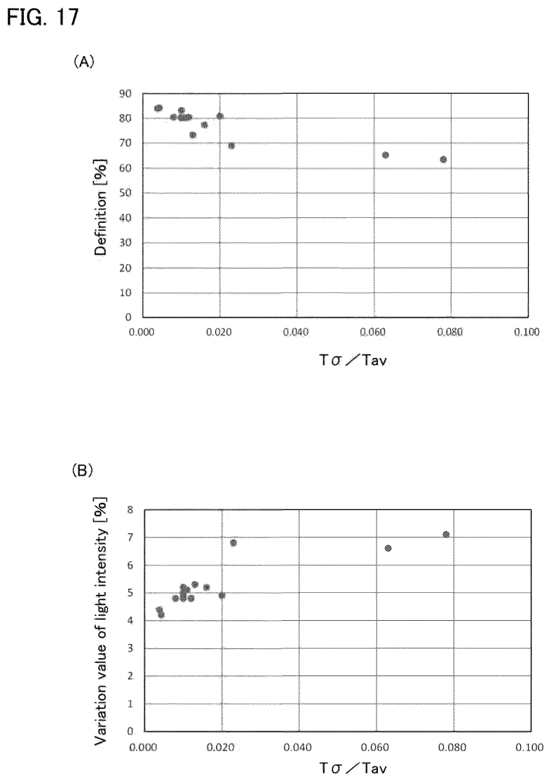

For the glass substrate in Examples I-1 to I-10 and Comparative Examples I-1 to I-6, the relation between the variation coefficient (T_{σ}/Tₐᵥ) of the thickness (horizontal axis) and the image definition (vertical axis) is shown in FIG. 17(A). The relation between the variation coefficient (T_{σ}/Tₐᵥ) of the thickness (horizontal axis) and the variation value of the light intensity (vertical axis) is shown in FIG. 17(B).

As shown in FIGS. 16, it was confirmed that when CS_{σ}/CSₐᵥ was 0.09 or less, the image definition was 70% or more, and the variation value of the light intensity was 6.5% or less. As shown in FIGS. 17, when T_{σ}/Tₐᵥ was 0.050 or less, although the image definition tended to be high and the variation value of the light intensity tended to be small the image definition was low and the variation value of the light intensity was large in some cases, and it was confirmed that CS_{σ}/CSₐᵥ had a greater influence on the glass texture than T_{σ}/Tₐᵥ.

### II. Examples Relating to Glass Stacked Body

### [Preparation of Glass Substrate]

A glass substrate having the thickness (T₁) shown in Table 2 was subjected to a chemically strengthening treatment, and a chemically strengthened glass wherein the first surface has the surface compressive stress (average value (CSₐᵥ), standard deviation (CS_{σ}), and variation coefficient (CS_{σ}/CSₐᵥ)) shown in Table 2 was obtained. Incidentally, the thickness (T₁) of the glass substrate was obtained by preparing 9 areas by dividing the glass substrate into 3 respective areas in the first direction (x direction) and the second direction (y direction) perpendicular to the first direction, in a surface parallel to the first surface and the second surface; measuring the thickness at one point in each area; and determining the arithmetic average of the 9 measurement points.

Also, the measurement of the average value (CSₐᵥ), standard deviation (CS_{σ}), and variation coefficient (CS_{σ}/CSₐᵥ) of surface compressive stress value were carried out as follows.

[Average Value (CSₐᵥ), Standard Deviation (CS_{σ}), and Variation Coefficient (CS_{σ}/CSₐᵥ) of Surface Compressive Stress Value]

For the glass substrate, the average value (CSₐᵥ) of surface compressive stress value was obtained by preparing 9 areas by dividing the first surface of the glass substrate into 3 respective areas in the first direction (x direction) and the second direction (y direction) perpendicular to the first direction, in the surface; measuring the surface compressive stress value CS at one point in each area; and determining the arithmetic average of the 9 measurement points. A refractometer type glass surface stress meter FSM-6000LE from Iuceo Co., Ltd. was used to measure the surface compressive stress CS. Further, the standard deviation (CS_{σ}), and variation coefficient (CS_{σ}/CSₐᵥ) of these measured values were measured.

Also, the glass transition point (Tg) of the joining layer was measured using the method described in “E. Glass stacked body (second embodiment)”.

### [Production of Glass Stacked Body]

### Example II-1

Firstly, a resin substrate with a thickness of 50 μm (“A4160 (current part number)” (“A4100 (former part number)” from TOYOBO Co., Ltd., a composite elastic modulus of 6.9 GPa) was coated with the following hard coating composition, and a hard coating layer with a thickness of 10 μm was formed. Thereby, a hard coating film (resin layer) with a thickness of 60 μm was prepared.

### Hard Coating Composition

A hard coating composition was prepared by compounding each component so as to be the composition shown below.
Mixture of dipentaerythritol pentaacrylate and dipentaerythritol hexaacrylate (M403 from Toagosei Co., Ltd.): 25 parts by mass
Dipentaerythritol EO modified hexaacrylate (A-DPH-6E from Shin-Nakamura Chemical Co., Ltd.): 25 parts by mass
Deformed silica fine particle (average particle size: 25 nm, from JGC Catalysts and Chemicals Ltd.): 50 parts by mass (in terms of solid)
Photopolymerization initiator (Irg184): 4 parts by mass
Fluorine based leveling agent (F568 from DIC Corporation): 0.2 parts by mass (in terms of solid)
Ultraviolet ray absorber 1 (DAINSORB P6, from Daiwa Kasei Co., Ltd.) 3 parts by mass
Solvent (MIBK): 150 parts by mass

Then the resin substrate layer side surface of the hard coating film was coated with the following heat-sensitive adhesive layer material so that the thickness after drying was 5 μm, dried at 100° C. for 1 minute to form a heat-sensitive adhesive layer (joining layer). Thereby, a hard coating film with a heat-sensitive adhesive layer was obtained.

### Heat-Sensitive Adhesive Layer Material

Amorphous polyester based resin (Byron 240, from Toyobo Co., Ltd.): 100 parts by mass
Hexane methylene diisocyanate (Coronate 2203 from Tosoh Corporation (former Nippon Polyurethane Industry Co., Ltd.): 5 parts by mass
Silane coupling agent (KBM-403 from Shin-Etsu Chemical Co., Ltd.): 5 parts by mass
Fluorine based leveling agent (F568 from DIC Corporation): 0.2 parts by mass (in terms of solid)
Solvent (MEK): 310 parts by mass
Solvent (toluene): 310 parts by mass

The obtained hard coating film with a heat-sensitive adhesive layer was disposed so that the heat-sensitive adhesive layer side surface was in contact with the first surface of the glass substrate prepared above. A stacked body was obtained by disposing a glass supporting substrate with a thickness of 2 mm on the surface of the glass substrate that is opposite side to the hard coating film with a heat-sensitive adhesive layer; and adhering the hard coating film with a heat-sensitive adhesive layer and glass substrate using a roll laminator (product name: Deaktop Roll Laminator B35A3 from ACCO Brands Japan K. K.), while heating. In doing so, the roll temperature was 140° C. to 149° C. and the feeding speed was 0.3 m/min. The stacked body was then aged for two days at 70° C. The composite elastic modulus of the joining layer in the stacked body was 4.2 GPa.

### Example II-2 and Example II-3

A glass stacked body was produced in the same manner as in Example II-1 except that the thickness (T₁), and average value (CSₐᵥ), standard deviation (CS_{σ}), and variation coefficient (CS_{σ}/CSₐᵥ) of the surface compressive stress value, of the glass substrate, were changed to those shown in Table 2.

### Example II-4

The thickness (T₁), and average value (CSₐᵥ), standard deviation (CS_{σ}), and variation coefficient (CS_{σ}/CSₐᵥ) of the surface compressive stress value, of the glass substrate, were changed to those shown in Table 2. Also, a glass stacked body was produced in the same manner as in Example II-1 except that the heat-sensitive adhesive layer material was changed to the following compound composition; the joining layer (composite elastic modulus of 2.4 GPa) was formed so that the thickness after drying was the thickness shown in Table 2; the resin layer was a hard coating film with a thickness of 70 μm (including a hard coating layer with a thickness of 20 μm formed on a resin substrate with a thickness of 50 μm (“A4160 (current part number)” (“A4100 (former part number)”) from TOYOBO Co., Ltd., and a composite elastic modulus of 6.9 GPa).

Compounding of joining layer
Polyester urethane based resin (UR-8300, solid content of 30%, from Toyobo Co., Ltd.): 100 parts by mass
Hexane methylene diisocyanate (Coronate 2203 from Tosoh Corporation (former Nippon Polyurethane Industry Co., Ltd.)): 1.5 parts by mass
Silane coupling agent (KBM-403 from Shin-Etsu Chemical Co., Ltd.): 1.5 parts by mass
Fluorine based leveling agent (F568 from DIC Corporation): 0.2 parts by mass (in terms of solid)
Solvent (MEK): 58 parts by mass
Solvent (toluene): 58 parts by mass

### Example II-5

Onto the glass stacked body sample produced in Example II-3, a hard coating film (second resin layer) with a thickness of 60 μm used in Example II-1 was adhered via a joining layer (OCA, NCF-D692 from LINTEC Corporation, a thickness of 15 μm, and a composite elastic modulus of 0.02 GPa). Incidentally, they were adhered so that the hard coating layer side surface of the hard coating film was on the outer side.

### Example II-6

A glass substrate with the thickness (T₁), and average value (CSₐᵥ), standard deviation (CS_{σ}), and variation coefficient (CS_{σ}/CSₐᵥ) of the surface compressive stress value, shown in Table 2, was produced. The glass substrate was coated with the following composition for a primer layer, and dried for 3 minutes at 80° C. and 60 minutes at 150° C. to form a primer layer with a thickness of 1 μm.

### <Primer Layer Composition>

Bisphenol A type solid epoxy resin (jER1256B40 from Mitsubishi Chemical Corporation): 28 parts by mass
Bisphenol A novolac type solid epoxy resin (jER157S65B80 from Mitsubishi Chemical Corporation): 5 parts by mass
2-ethyl-4-methylimidazole (from Tokyo Chemical Industry Co., Ltd.): 1 part by mass
Solvent (MEK): 11 parts by mass

Referring to the Synthesis Example 1 in WO2014/046180, a tetracarboxylic acid dianhydride represented by the following chemical formula was synthesized.

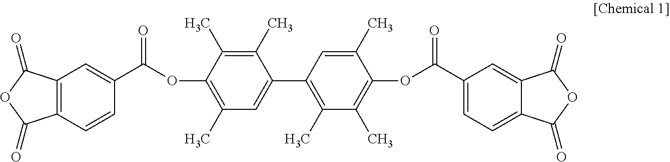 [SMILES: Cc1cc(-c2cc(C)c(OC(=O)c3ccc4c(c3)C(=O)OC4=O)c(C)c2C)c(C)c(C)c1OC(=O)c1ccc2c(c1)C(=O)OC2=O]

To a separable flask of 5 L, a solution wherein dehydrated N,N-dimethylacetamide (DMAc) (1833.2 g) and 2,2′-bis(trifluoromethyl)benzidine (TFMB) (138.48 g) were dissolved was added; controlling the liquid temperature to 30° C., the tetracarboxylic acid dianhydride (TMPBPTME) (176.70 g) represented by the above chemical formula was gradually charged so that the temperature rise was 2° C. or less; and stirred with a mechanical stirrer for 30 minutes. To the above, pyromellitic acid dianhydride (PMDA) (64.20 g) was gradually charged in several times, so that the temperature rise was 2° C. or less, to synthesize a polyimide precursor solution (18% by mass solid content) including dissolved polyimide precursor. The molar ratio (TMPBPTME:PMDA) of the tetracarboxylic acid dianhydride TMPBPTME and the PMDA used in the polyimide precursor was 90:10. The weight average molecular weight of the polyimide precursor was 75,000.

Under a nitrogen atmosphere, the polyimide precursor solution (2162 g) cooled to room temperature was added to a separable flask of 5 L. The dehydrated N,N-dimethylacetamide (432 g) was added thereto, and stirred until homogeneous. Then, pyridine (6.622 g) as a catalyst and acetic anhydride (213.67 g) were added, stirred at room temperature for 24 hours to synthesize a polyimide solution. To the obtained polyimide solution, N,N-dimethylacetamide (DMAc) (2000 g) was added and stirred until homogeneous. The polyimide solution was then divided into 3 equal parts into 5 L beakers, and isopropyl alcohol (3500 g) was gradually added to each beaker to obtain a white slurry. The slurry was transferred to the Buchner funnel and filtered; then, a process of washing with flowing isopropyl alcohol (9,000 g in total), and then filtering, was repeated for three times; the slurry was dried at 110° C. using a vacuum dryer to obtain polyimide (polyimide powder). The weight average molecular weight of the polyimide measured by GPC was 100000.

To the polyimide, N,N-dimethylacetamide (DMAc) was added so that the solid content concentration of the polyimide was 12% by mass, and a polyimide varnish (resin composition) including 12% by mass of the polyimide in varnish was prepared. The viscosity of the polyimide varnish (resin composition) (solid content concentration: 12% by mass) at 25° C. was 15000 cps.

The primer layer was coated with the polyimide varnish (resin composition) so that thickness after drying was 20 μm, dried for 5 minutes at 80° C., 10 minutes at 150° C., and 30 minutes at 230° C. to form a resin layer (composite elastic modulus of 6.2 GPa). Thereby, a glass stacked body was produced.

### Example II-7

A glass substrate with the thickness (T₁), and average value (CSₐᵥ), standard deviation (CS_{σ}), and variation coefficient (CS_{σ}/CSₐᵥ) of the surface compressive stress value shown in Table 2 was produced. A glass stacked body was produced in the same manner as in Example II-1 except that, using the produced glass substrate, the thickness of the joining layer was changed to the value (25 μm) shown in Table 2.

### Example II-8

A glass stacked body was produced in the same manner as in Example II-3 except that a polyester based material with a Tg of −20° C. was used as the material for the joining layer, and the thickness was 10 μm.

### Example II-9

A glass stacked body was produced in the same manner as in Example II-2 except that the material used in Example II-8 was used as the material for the joining layer, and the thickness was 6 μm.

### Comparative Example II-1

A glass substrate with the thickness (T₁), and average value (CSₐᵥ), standard deviation (CS_{σ}), and variation coefficient (CS_{σ}/CSₐᵥ) of the surface compressive stress value shown in Table 2 was produced. The hard coating film with a thickness of 60 μm used in Example II-1 and the glass substrate were adhered via a joining layer with a thickness of 50 μm (an optically clear adhesive film (OCA) (“8146-2” from 3M Japan Limited, composite elastic modulus of 9.6 MPa)), using a hand roller. Incidentally, they were adhered so that the substrate layer side surface of the hard coating film was on the glass substrate side.

### Comparative Examples II-2 and Comparative Example II-3

A glass stacked body was produced in the same manner as in Example II-1 except that a glass surface having the thickness (T₁), and average value (CSₐᵥ), standard deviation (CS_{σ}), and variation coefficient (CS_{σ}/CSₐᵥ) of the surface compressive stress value shown in Table 2 was produced.

### Comparative Example II-4

A glass substrate with the thickness (T₁), and average value (CSₐᵥ), standard deviation (CS₀), and variation coefficient (CS_{σ}/CSₐᵥ) of the surface compressive stress value shown in Table 2 was produced. The hard coating film with a thickness of 60 μm used in Example II-1 and the glass substrate were adhered via a joining layer with a thickness of 50 μm (an optically clear adhesive film (OCA) (“8146-2” from 3M Japan Limited, composite elastic modulus of 9.6 MPa)), using a hand roller, and obtained a glass stacked body. Incidentally, they were adhered so that the substrate layer side surface of the hard coating film was on the glass substrate side.

### Comparative Example II-5

A glass substrate with the thickness (T₁), and average value (CSₐᵥ), standard deviation (CS_{σ}), and variation coefficient (CS_{σ}/CSₐᵥ) of the surface compressive stress value shown in Table 2 was produced. Also, a resin layer with a thickness of 10 μm was formed on the first surface side of the glass substrate in the same manner as in Example II-6.

### Comparative Example II-6

A glass stacked body was obtained by adhering a hard coating film (second resin layer), in the same manner as in Example II-5, to the glass stacked body obtained in Comparative Example II-4.

The total thickness T₀ of the glass stacked body in Examples II-1 to II-7 and Comparative Examples II-1 to II-6, and the ratio (%) of the total thickness T₂ of the joining layer with respect to the total thickness T₀ were calculated. The calculated values are shown in Table 2. The glass substrate wherein a joining layer and a resin layer are not formed is shown in Table 2 as Reference Examples 1 to 4.

TABLE 2

| | | | | | Joining layer | | | | Resin layer | | | | |
|---|---|---|---|---|---|---|---|---|---|---|---|---|---|
| | | | | | 1^{st} | 1^{st} | 2^{nd} | | 1^{st} | | | Stacked | Joining |
| | Glass substrate | | | | joining | joining | joining | Joining | resin | 2^{nd} | Resin | body | layer |
| | Thk | | | | ly thk | layer | ly thk | ly ttl | ly thk | resin | ly ttl | total | ratio |
| | T₁ | CSav | CSσ | CSσ/ | T₂ₐ | Tg | T_{2b} | thk T₂ | T₃ₐ | ly thkT_{3b} | thk T₃ | thk T₀ | (T₂/T₀) × 100 |
| | [μm] | [MPa] | [MPa] | CSav | [μm] | [° C.] | [μm] | [μm] | [μm] | [μm] | [μm] | [μm] | [%] |
| Ref. Ex. 1 | 69 | 610 | 8.5 | 0.014 | — | — | — | — | — | — | — | — | — |
| Ref. Ex. 2 | 51 | 580 | 10.6 | 0.018 | — | — | — | — | — | — | — | — | — |
| Ref. Ex. 3 | 31 | 520 | 24.4 | 0.047 | — | — | — | — | — | — | — | — | — |
| Ref. Ex. 4 | 59 | 850 | 90.3 | 0.306 | — | — | — | — | — | — | — | — | — |
| Ex. II-1 | 69 | 610 | 8.5 | 0.014 | 5 | 30 | — | 5 | 60 | — | 60 | 134 | 4 |
| Ex. II-2 | 51 | 580 | 10.6 | 0.018 | 5 | 30 | — | 5 | 60 | — | 60 | 116 | 4 |
| Ex. II-3 | 31 | 520 | 24.4 | 0.047 | 5 | 30 | — | 5 | 60 | — | 60 | 96 | 5 |
| Ex. II-4 | 31 | 520 | 24.4 | 0.047 | 15 | 30 | — | 15 | 70 | — | 70 | 116 | 13 |
| Ex. II-5 | 31 | 520 | 24.4 | 0.047 | 5 | 30 | 15 | 20 | 60 | 60 | 120 | 171 | 12 |
| Ex. II-6 | 100 | 770 | 7.2 | 0.009 | — | — | — | 0 | 20 | — | 20 | 120 | 0 |
| Ex. II-7 | 140 | 640 | 4.5 | 0.007 | 25 | 30 | — | 25 | 60 | — | 60 | 225 | 11 |
| Ex. II-8 | 31 | 520 | 24.4 | 0.047 | 10 | −20 | — | 10 | 60 | — | 60 | 101 | 10 |
| Ex. II-9 | 51 | 580 | 10.6 | 0.018 | 6 | −20 | — | 6 | 60 | — | 60 | 117 | 5 |
| Comp. Ex. II-1 | 51 | 580 | 10.6 | 0.018 | 50 | −10 | — | 50 | 60 | — | 60 | 161 | 31 |
| Comp. Ex. II-2 | 52 | 850 | 90.3 | 0.106 | 5 | 30 | — | 5 | 60 | — | 60 | 117 | 4 |
| Comp. Ex. II-3 | 59 | 923 | 96.7 | 0.105 | 5 | 30 | — | 5 | 60 | — | 60 | 124 | 4 |
| Comp. Ex. II-4 | 31 | 520 | 24.4 | 0.047 | 50 | −10 | — | 50 | 60 | — | 60 | 141 | 35 |
| Comp. Ex. II-5 | 31 | 520 | 24.4 | 0.047 | — | — | — | 0 | 10 | — | 10 | 41 | 0 |
| Comp. Ex. II-6 | 31 | 520 | 24.4 | 0.047 | 50 | −10 | 15 | 65 | 60 | 60 | 120 | 216 | 30 |

### [Evaluation 1 Image Definition]

For the glass stacked body in Examples II-1 to II-7 and Comparative Examples II-1 to II-6, an evaluation sample shown in FIG. 11 described above was prepared, using the resin layer side surface as the surface to be measured 21, and the image definition was measured by the method described in “D. Glass stacked body (fourth embodiment)” above. Also, the image definition of the glass substrate in Reference Examples 1 to 4 was measured in the same way. The results are shown in Table 3.

### [Evaluation 2 Variation Value of Light Intensity]

For the glass stacked body in Examples II-1 to II-7 and Comparative Examples II-1 to II-6, the variation value of the light intensity was measured by the method described in “C. Glass stacked body (third embodiment)” above. Also, the variation value of the light intensity of the glass substrate in Reference Examples 1 to 4 was measured in the same way. The results are shown in Table 3.

### [Evaluation 3 Visual Evaluation]

Using an LED light source, light was illuminated, from the resin layer side, on the glass stacked body in Examples II-1 to II-7 and Comparative Examples II-1 to II-6, reflected, visually observed form the resin layer side, and evaluated under the following evaluation criteria. The results are shown in Table 3. The observations were carried out indoors (not in a darkroom). Also, the glass substrate in Reference Examples 1 to 4 was visually observed in the same way. The results are shown in Table 3.

### Evaluation Criteria

The visual observation was carried out by 20 people, and evaluated by the number of people who found no deformation nor unevenness.
A: 18 people or more
B: 10 people or more
C: 5 people or more
D: 4 people or less

### [Evaluation 4 U-Shaped Bending Test]

The U-shaped bending test described above was carried out to the glass stacked body in Examples II-1 to II-7, Comparative Examples II-1 to II-6, and the glass substrate in Reference Examples 1 to 4. In the test of the glass stacked body, the glass stacked body was folded so that the resin layer side is on the inner side, and the glass substrate side is on the outer side. The minimum value of the distance “d” (mm) between the two facing short side portions of the glass stacked body or glass substrate, at which a crack or a fracture did not occur in the glass stacked body or glass substrate was measured. The results are shown in Table 3.

### [Evaluation 5 Impact Test (Pen Dropping Test)]

An impact test was carried out to the glass stacked body in Examples II-1 to II-7 and Comparative Examples II-1 to II-6. Firstly, a stacked body for a test was produced by adhering an optically clear adhesive film (OCA) with a thickness of 50 μm and a PET film with a thickness of 100 μm onto the glass substrate side surface of the glass stacked body, in this order. The stacked body for a test was disposed on a metal plate with a thickness of 30 mm so that the PET film side surface of the stacked body for a test was in contact with the metal plate. Then, a pen was dropped to the stacked body for a test with its tip down, from a testing height. As the pen, Blen 0.5 BAS88-BK (weight: 12 g, pen tip: 0.5 mm φ) from Zebra Co., Ltd. was used. The maximum testing height (cm) at which the glass stacked body was not broken was measured. The results are shown in Table 3. Incidentally, the higher the value, the higher the impact resistance.

TABLE 3

| | | Variation | | U- | |
|---|---|---|---|---|---|
| | | value | | shaped | |
| | Image | of light | | bending | Impact |
| | definition | intensity | Visual | test | test |
| | [%] | [%] | Observation | [mm] | [cm] |
| Ref. Ex. 1 | 80.5 | 4.8 | A | 3 | 7 |
| Ref. Ex. 2 | 80.9 | 4.9 | A | 2 | 4 |
| Ref. Ex. 3 | 73.3 | 5.3 | B | 1.5 | 2 |
| Ref. Ex. 4 | 63.5 | 7.1 | C | 6 | 10 |
| Ex. II-1 | 80.5 | 5.7 | A | 5 | 47 |
| Ex. II-2 | 78.3 | 6.5 | A | 4 | 24 |
| Ex. II-3 | 76.4 | 7.7 | A | 3 | 20 |
| Ex. II-4 | 70.1 | 7.3 | B | 3 | 19 |
| Ex. II-5 | 73.3 | 8.0 | B | 4 | 38 |
| Ex. II-6 | 80.5 | 4.8 | A | 7 | 50< |
| Ex. II-7 | 73.5 | 7.7 | B | 6 | 50< |
| Ex. II-8 | 74.5 | 8.0 | B | 4 | 20 |
| Ex. II-9 | 74.5 | 87.2 | A | 5 | 24 |
| Comp. Ex. II-1 | 60.6 | 14.3 | C | 3 | 28 |
| Comp. Ex. II-2 | 36.3 | 11.3 | D | 7 | 28 |
| Comp. Ex. II-3 | 37.5 | 16.6 | D | 9 | 29 |
| Comp. Ex. II-4 | 56.3 | 19.9 | D | 4 | 22 |
| Comp. Ex. II-5 | 76.2 | 5.5 | A | 2 | 6 |
| Comp. Ex. II-6 | 50.0 | 19.6 | D | 4 | 42 |

As shown in Table 3, there was a correlation between the evaluation results of visual test and image definition. Also, there was a correlation between the evaluation results of the visual test and the variation value of the light intensity.

It was confirmed that the glass stacked body in the present disclosure had excellent bending resistance and impact resistance, and also having excellent glass texture (Examples II-1 to II-7).

Meanwhile, it was confirmed that, when the glass substrate with the average value (CSₐᵥ) of the surface compressive stress value, of the first surface, of more than 800 MPa was used, the bending resistance was inferior; and when the glass substrate with the ratio (CS_{σ}/CSₐᵥ) of the standard deviation (CS_{σ}) of the surface compressive stress value with respect to the average value (CSₐᵥ) of the surface compressive stress value of more than 0.090 was used, good glass texture could not be obtained (Comparative Examples II-2, II-3). Also, it was confirmed that, even when glass substrates with good glass texture in Reference Examples 2 and 3 were used, good glass texture could not be obtained when the total thickness of the joining layer was more than 25% with respect to the thickness of the glass stacked body (Comparative Examples II-1, II-4, and II-6). Also, it was confirmed that, when the thickness of the glass stacked body was less than 50 μm, the impact resistance was inferior (Comparative Example II-5).

Further, by the comparison between Example II-8 and Example II-5, and between Example II-9 and Example II-2, it was revealed that the higher the temperature of the glass transition point (Tg) of the joining layer, the better the image definition value.

Incidentally, the present disclosure includes the following inventions.

[1]

A glass substrate comprising: a first surface, and a second surface facing the first surface, wherein
the glass substrate is a chemically strengthened glass;
an average value (Tₐᵥ) of a thickness of the glass substrate is 20 μm or more and 200 μm or less; and at least for the first surface of the glass substrate, an average value (CSₐᵥ) of a surface compressive stress value is 400 MPa or more and 800 MPa or less, and a ratio (CS_{σ}/CSₐᵥ) of a standard deviation (CS_{σ}) of the surface compressive stress value with respect to the average value (CSₐᵥ) of the surface compressive stress value is 0.090 or less.
   [2]

The glass substrate according to [1], wherein a ratio (T_{σ}/Tₐᵥ) of a standard deviation (T_{σ}) of the thickness with respect to the average value (Tₐᵥ) of the thickness is 0.003 or more and 0.050 or less.

[3]

The glass substrate according to [1] or [2], wherein a depth (DOL) of a compressive stress layer of the first surface is 5 μm or more and 20 μm or less.

[4]

The glass substrate according to any one of [1] to [3], wherein an internal tensile stress (CT) is 80 MPa or more and 350 MPa or less.

[5]

The glass substrate according to any one of [1] to [4], wherein, when the glass substrate is disposed on a horizontal base table, a maximum distance of a gap to the base table is:
0.6 mm or less, when a test piece is the glass substrate of 100 mm×100 mm size; or
20 mm or less, when a test piece is the glass substrate of 280 mm×320 mm size.
   [6]

The glass substrate according to any one of [1] to [5], wherein a variation value of a light intensity measured, from a first surface side, by a following method for measuring surface properties is 6.5% or less.

### [Method for Measuring Surface Properties]

(1) Illuminate an illumination light, including four linear bright regions and dark regions, on a surface to be measured that is the first surface of the glass substrate.

(2) Focusing on the surface to be measured with an imaging device, reflect the illumination light on the surface to be measured; receive reflected light including linear bright regions and dark regions corresponding to the bright regions and the dark regions of the illumination light; and detect a light intensity distribution of the reflected light on the surface to be measured.

(3) Divide the light intensity distribution of the reflected light, on the surface to be measured, into 1,100 segment regions in a longitudinal direction of the linear bright region of the reflected light; and determine a light intensity at a position a predetermined value away from a position where a peak value of the light intensity is indicated, per the segment region and per the bright region.

(4) Determine a variation coefficient of the light intensity for each bright region; and calculate an arithmetic average value of variation coefficients for the four bright regions.

[7]

The glass substrate according to any one of [1] to [6], wherein a reflected image definition measured from a first surface side is 70% or more.

[8]

A glass substrate comprising: a first surface and a second surface facing the first surface, wherein
the glass substrate is a chemically strengthened glass;
an average value (Tₐᵥ) of a thickness of the glass substrate is 20 μm or more and 200 μm or less;
at least for the first surface of the glass substrate, an average value (CSₐᵥ) of a surface compressive stress value is 400 MPa or more and 800 MPa or less; and
a variation value of a light intensity measured, from a first surface side, by a following method for measuring surface properties is 6.5% or less.

### [Method for Measuring Surface Properties]

(1) Illuminate an illumination light, including four linear bright regions and dark regions, on a surface to be measured that is the first surface of the glass substrate.

(2) Focusing on the surface to be measured with an imaging device, reflect the illumination light on the surface to be measured; receive reflected light including linear bright regions and dark regions corresponding to the bright regions and the dark regions of the illumination light; and detect a light intensity distribution of the reflected light on the surface to be measured.

(3) Divide the light intensity distribution of the reflected light, on the surface to be measured, into 1,100 segment regions in a longitudinal direction of the linear bright region of the reflected light; and determine a light intensity at a position a predetermined value away from a position where a peak value of the light intensity is indicated, per the segment region and per the bright region.

(4) Determine a variation coefficient of the light intensity for each bright region; and calculate an arithmetic average value of variation coefficients for the four bright regions.

[9]

The glass substrate according to [8], wherein a reflected image definition measured from a first surface side is 70% or more.

[10]

A glass substrate comprising: a first surface, and a second surface facing the first surface, wherein
the glass substrate is a chemically strengthened glass;
an average value (Tₐᵥ) of a thickness of the glass substrate is 20 μm or more and 200 μm or less;
at least for the first surface of the glass substrate, an average value (CSₐᵥ) of a surface compressive stress value is 400 MPa or more and 800 MPa or less; and
a reflected image definition measured from a first surface side is 70% or more.
   [11]

A glass stacked body comprising:
the glass substrate according to any one of [1] to [10]; and
a resin layer disposed on at least one of a first surface side and a second surface side of the glass substrate.
   [12]

A glass stacked body comprising:
the glass substrate according to any one of [1] to [7]; and
a resin layer disposed on a first surface side of the glass substrate, wherein
a thickness of the glass stacked body is 50 μm or more and 300 μm or less; and
the glass stacked body includes a joining layer disposed on a first surface side of the glass substrate, and a total thickness of the joining layer, with respect to a thickness of the glass stacked body, is 25% or less.
   [13]

A glass stacked body comprising:
the glass substrate according to any one of [1] to [7]; and
a resin layer disposed on a first surface side of the glass substrate, wherein
a thickness of the glass stacked body is 50 μm or more and 300 μm or less; and
in the glass stacked body, the resin layer is in contact with the glass substrate.
   [14]

The glass stacked body according to [12] or [13], wherein a total thickness of the resin layer is 10 μm or more and 100 μm or less.

[15]

The glass stacked body according to any one of [12] to [14], wherein, for the glass stacked body, a variation value of a light intensity measured, from a resin layer side, by a following method for measuring surface properties is 10.5% or less.

### [Method for Measuring Surface Properties]

(1) Illuminate an illumination light, including four linear bright regions and dark regions, on a surface to be measured that is a surface of the resin layer of the glass stacked body.

(2) Focusing on the surface to be measured with an imaging device, reflect the illumination light on the surface to be measured; receive reflected light including linear bright regions and dark regions corresponding to the bright regions and the dark regions of the illumination light; and detect a light intensity distribution of the reflected light on the surface to be measured.

(3) Divide the light intensity distribution of the reflected light, on the surface to be measured, into 1,100 segment regions in a longitudinal direction of the linear bright region of the reflected light; and determine a light intensity at a position a predetermined value away from a position where a peak value of the light intensity is indicated, per the segment region and per the bright region.

(4) Determine a variation coefficient of the light intensity for each bright region; and calculate an arithmetic average value of variation coefficients for the four bright regions.

[16]

The glass stacked body according to any one of [12]to [15], wherein, for the glass stacked body, a reflected image definition measured from a resin layer side is 65% or more.

[17]

A glass stacked body comprising:
a glass substrate including a first surface, and a second surface facing the first surface; and
a resin layer disposed on a first surface side of the glass substrate, wherein
the glass substrate is a chemically strengthened glass, and a thickness of the glass substrate is 20 μm or more and 200 μm or less;
at least for the first surface of the glass substrate, an average value (CSₐᵥ) of a surface compressive stress value is 400 MPa or more and 800 MPa or less;
a thickness of the glass stacked body is 50 μm or more; and
for the glass stacked body, a variation value of a light intensity measured, from a resin layer side, by a following method for measuring surface properties is 10.5% or less.

### [Method for Measuring Surface Properties]

(1) Illuminate an illumination light, including four linear bright regions and dark regions, on a surface to be measured that is a surface of the resin layer of the glass stacked body.

(2) Focusing on the surface to be measured with an imaging device, reflect the illumination light on the surface to be measured; receive reflected light including linear bright regions and dark regions corresponding to the bright regions and the dark regions of the illumination light; and detect a light intensity distribution of the reflected light on the surface to be measured.

(3) Divide the light intensity distribution of the reflected light, on the surface to be measured, into 1,100 segment regions in a longitudinal direction of the linear bright region of the reflected light; and determine a light intensity at a position a predetermined value away from a position where a peak value of the light intensity is indicated, per the segment region and per the bright region.

(4) Determine a variation coefficient of the light intensity for each bright region; and calculate an arithmetic average value of variation coefficients for the four bright regions.

[18]

The glass stacked body according to [17], wherein a reflected image definition measured from a resin layer side is, 65% or more.

[19]

A glass stacked body comprising:
a glass substrate including a first surface and a second surface facing the first surface; and
a resin layer disposed on a first surface side of the glass substrate, wherein
the glass substrate is a chemically strengthened glass, and a thickness of the glass substrate is 20 μm or more and 200 μm or less;
at least for the first surface of the glass substrate, an average value (CSₐᵥ) of a surface compressive stress value is 400 MPa or more and 800 MPa or less; and
a thickness of the glass stacked body is 50 μm or more, and a reflected image definition measured from a resin layer side is 65% or more.
   [20]

A member for a display device comprising the glass stacked body according to any one of [11] to [19]; and a functional layer disposed on a resin layer side of the glass stacked body.

[21]

A display device comprising a display panel; and the glass substrate according to any one of [1] to [10] disposed on an observer side of the display panel.

[22]

A display device comprising:
a display panel; and
the glass stacked body according to any one of [11] to [19], or the member for a display device according to [20] disposed on an observer side of the display panel, wherein
the glass stacked body or the member for a display device is disposed so that a resin layer side of the glass stacked body is on an observer side.
   [23]

A method for inspecting a glass substrate including a first surface and a second surface facing the first surface, and the glass substrate is a chemically strengthened glass, the method comprising:
a step of selecting a glass substrate having a variation value of a light intensity measured, from a first surface side, by a following method for measuring surface properties of 6.5% or less.

### [Method for Measuring Surface Properties]

(1) Illuminate an illumination light, including four linear bright regions and dark regions, on a surface to be measured that is the first surface of the glass substrate.

(2) Focusing on the surface to be measured with an imaging device, reflect the illumination light on the surface to be measured; receive reflected light including linear bright regions and dark regions corresponding to the bright regions and the dark regions of the illumination light; and detect a light intensity distribution of the reflected light on the surface to be measured.

(3) Divide the light intensity distribution of the reflected light, on the surface to be measured, into 1,100 segment regions in a longitudinal direction of the linear bright region of the reflected light; and determine a light intensity at a position a predetermined value away from a position where a peak value of the light intensity is indicated, per the segment region and per the bright region.

(4) Determine a variation coefficient of the light intensity for each bright region; and calculate an arithmetic average value of variation coefficients for the four bright regions.

[24]

The method for inspecting a glass substrate according to [23], further comprising a step of selecting a glass substrate having a reflected image definition, measured from a first surface side, of 70% or more.

[25]

A method for inspecting a glass substrate including a first surface and a second surface facing the first surface, and the glass substrate is a chemically strengthened glass, the method comprising a step of selecting a glass substrate having a reflected image definition, measured from a first surface side, of 70% or more.

[26]

A method for inspecting a glass stacked body including a glass substrate that is a chemically strengthened glass and including a first surface, and a second surface facing the first surface; and a resin layer disposed on a first surface side of the glass substrate, the method comprising
a step of selecting a glass stacked body having a variation value of a light intensity measured, from a resin layer side, by a following method for measuring surface properties of 10.5% or less.

### [Method for Measuring Surface Properties]

(1) Illuminate an illumination light, including four linear bright regions and dark regions, on a surface to be measured that is a surface of the resin layer of the glass stacked body.

(2) Focusing on the surface to be measured with an imaging device, reflect the illumination light on the surface to be measured; receive reflected light including linear bright regions and dark regions corresponding to the bright regions and the dark regions of the illumination light; and detect a light intensity distribution of the reflected light on the surface to be measured.

(3) Divide the light intensity distribution of the reflected light, on the surface to be measured, into 1,100 segment regions in a longitudinal direction of the linear bright region of the reflected light; and determine a light intensity at a position a predetermined value away from a position where a peak value of the light intensity is indicated, per the segment region and per the bright region.

(4) Determine a variation coefficient of the light intensity for each bright region; and calculate an arithmetic average value of variation coefficients for the four bright regions.

[27]

The method for inspecting a glass stacked body according to [26], further comprising a step of selecting a glass stacked body having a reflected image definition, measured from a resin layer side, of 65% or more.

[28]

A method for inspecting a glass stacked body including a glass substrate that is a chemically strengthened glass and including a first surface, and a second surface facing the first surface; and a resin layer disposed on a first surface side of the glass substrate, the method comprising a step of selecting a glass stacked body having a reflected image definition, measured from a resin layer side, of 65% or more.

[29]

A method for producing a display device, the method comprising a glass substrate inspecting step of carrying out the method for inspecting a glass substrate according to any one of [23] to [25].

[30]

A method for producing a display device, the method comprising a glass stacked body inspecting step of carrying out the method for inspecting a glass stacked body according to any one of [26] to [28].

### REFERENCE SIGNS LIST

1: glass substrate
1A: first surface of glass substrate
1B: second surface of glass substrate
10: glass stacked body
11, 12: resin layer
20: display device
21: display panel.

1-16. (canceled)

17. A glass stacked body comprising:
a glass substrate including a first surface, and a second surface facing the first surface; and
a resin layer disposed on a first surface side of the glass substrate, wherein
the glass substrate is a chemically strengthened glass, and a thickness of the glass substrate is 20 μm or more and 200 μm or less;
at least for the first surface of the glass substrate, an average value (CSₐᵥ) of a surface compressive stress value is 400 MPa or more and 800 MPa or less;
a thickness of the glass stacked body is 50 μm or more; and
for the glass stacked body, a variation value of a light intensity measured, from a resin layer side, by a following method for measuring surface properties is 10.5% or less.
[Method for measuring surface properties]
(1) Illuminate an illumination light, including four linear bright regions and dark regions, on a surface to be measured that is a surface of the resin layer of the glass stacked body.
(2) Focusing on the surface to be measured with an imaging device, reflect the illumination light on the surface to be measured; receive reflected light including linear bright regions and dark regions corresponding to the bright regions and the dark regions of the illumination light; and detect a light intensity distribution of the reflected light on the surface to be measured.
(3) Divide the light intensity distribution of the reflected light, on the surface to be measured, into 1,100 segment regions in a longitudinal direction of the linear bright region of the reflected light; and determine a light intensity at a position a predetermined value away from a position where a peak value of the light intensity is indicated, per the segment region and per the bright region.
(4) Determine a variation coefficient of the light intensity for each bright region; and calculate an arithmetic average value of variation coefficients for the four bright regions.

18. The glass stacked body according to claim 17, wherein a reflected image definition measured from a resin layer side is, 65% or more.

19. A glass stacked body comprising:
a glass substrate including a first surface and a second surface facing the first surface; and
a resin layer disposed on a first surface side of the glass substrate, wherein
the glass substrate is a chemically strengthened glass, and a thickness of the glass substrate is 20 μm or more and 200 μm or less;
at least for the first surface of the glass substrate, an average value (CSₐᵥ) of a surface compressive stress value is 400 MPa or more and 800 MPa or less; and
a thickness of the glass stacked body is 50 μm or more, and a reflected image definition measured from a resin layer side is 65% or more.

20. A member for a display device comprising the glass stacked body according to claim 17; and a functional layer disposed on a resin layer side of the glass stacked body.

21. (canceled)

22. A display device comprising:
a display panel; and
the glass stacked body according to claim 17 disposed on an observer side of the display panel, wherein
the glass stacked body or the member for a display device is disposed so that a resin layer side of the glass stacked body is on an observer side.

23-30. (canceled)

31. A member for a display device comprising the glass stacked body according to claim 19; and a functional layer disposed on a resin layer side of the glass stacked body.

32. A display device comprising:
a display panel; and
the glass stacked body according to claim 19 disposed on an observer side of the display panel, wherein
the glass stacked body or the member for a display device is disposed so that a resin layer side of the glass stacked body is on an observer side.

33. A display device comprising:
a display panel; and
the member for a display device according to claim 20 disposed on an observer side of the display panel, wherein
the glass stacked body or the member for a display device is disposed so that a resin layer side of the glass stacked body is on an observer side.

34. A display device comprising:
a display panel; and
the member for a display device according to claim 31 disposed on an observer side of the display panel, wherein
the glass stacked body or the member for a display device is disposed so that a resin layer side of the glass
